(19) United States
(12) Patent Application Publication
(10) Pub. No.: US 2018/0039174 A1
(43) Pub. Date: Feb. 8, 2018

(54) PHOTOSENSITIVE RESIN COMPOSITION

(71) Applicant: TORAY INDUSTRIES, INC., Tokyo (JP)

(72) Inventor: Yoshifumi IKEDA, Otsu-shi, Shiga (JP)

(73) Assignee: TORAY INDUSTRIES, INC., Tokyo (JP)

(21) Appl. No.: 15/556,215

(22) PCT Filed: Mar. 15, 2016
(86) PCT No.: PCT/JP2016/058175

§ 371 Date: Sep. 6, 2017

(30) Foreign Application Priority Data
Mar. 26, 2015 (JP) 2015-064013

(51) Int. Cl. G03F 7/039; G03F 7/004; G03F 7/16; G03F 7/20; G03F 7/32; H01L 23/532; C08G 73/14; C08G 73/22; C08G 8/24; G03F 7/075; H01L 51/00; G03F 7/023; G03F 7/40

(52) U.S. Cl. CPC G03F 7/039; G03F 7/0233; G03F 7/0236; G03F 7/0046; G03F 7/162; G03F 7/168; G03F 7/2004; G03F 7/322; G03F 7/40; C08G 73/14; C08G 73/22; C08G 8/24; G03F 7/0757; H01L 51/0035; H01L 51/0043; H01L 23/53228; H01L 23/5329; H01L 51/52

(57) ABSTRACT

Regarding cured pattern films for semiconductor apparatuses, the present invention provides a photosensitive resin composition that is high in sensitivity and able to realize improved contact between a cured pattern film and metal wiring after a reflow process. The photosensitive resin composition includes an alkali-soluble resin which contains at least one selected from the group consisting of a resin (a-1) which contains, as primary component, a structure as represented by the undermentioned general formula (1), polyimides (a-2) and copolymers thereof, and a compound (c) which contains, as primary component, a structure as represented by the undermentioned general formula (2).

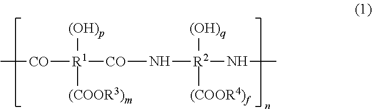

(In general formula (1), R¹ and R² may be identical to or different from each other and each represent a divalent to octavalent organic group having 2 or more carbon atoms; R³ and R⁴ may be identical to or different from each other and each represent either a hydrogen atom or an organic group having 1 to 20 carbon atoms; n is an integer of 10 to 100,000; m and f are independently an integer of 0 to 2; p and q are independently an integer of 0 to 4; and m+q≠0 and p+q≠0.)

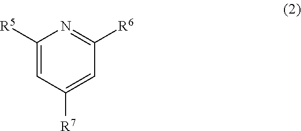

(In general formula (2), R⁵, R⁶, and R⁷ may be identical to or different from each other and each represent either a hydrogen atom or a monovalent organic group having 1 or more carbon atoms, and at least one of R⁵, R⁶, and R⁷ is a monovalent organic group having 1 or more carbon atoms.)

### TECHNICAL FIELD

The present invention relates to a photosensitive resin composition. More specifically, it relates to a positive type photosensitive resin composition that is suitable as material for surface protection films and interlaminar insulation films in semiconductor devices and insulation layers in organic electroluminescent devices.

### BACKGROUND ART

Having high heat resistance and good electrical insulating properties, such resins as polyimide and polybenzoxazole have been used as material for surface protection films and interlaminar insulation films in semiconductor devices and insulation layers in organic electroluminescent devices. As increasingly finer semiconductor devices are developed in recent years, there occur stronger demands for surface protection films and interlaminar insulation films that enable a resolution of a few micrometers. To this end, positive type photosensitive polyimide resin compositions and positive type photosensitive polybenzoxazole resin compositions are now used widely for these applications.

In the production of general semiconductor apparatuses, a semiconductor device is formed on a substrate and a passivation film of Si, SiN, or the like is formed thereon, followed by forming a resin film on the top to protect the surface of the semiconductor device. In a common production process, a resin film is formed over such a passivation film and then heat-dried using a hot plate or the like, followed by creating a pattern by light exposure and development steps. High temperature treatment by curing is carried out after the resin film patterning step.

General type semiconductor apparatuses containing bump electrodes have a structure in which metal wires designed for re-wiring are located on a pattern resin film formed on the electrode pad of a semiconductor chip and an electrode pad formed from a pattern resin film is added as insulation layer between the metal wires, followed by forming a bump electrode on the top. In a typical bump electrode production method, a bump electrode is formed by applying flux on an electrode pad of metal wiring, mounting a soldering ball, and performing reflowing operation to cause fusion bonding of the bump. In this process, the protection film and insulation film remain in contact with the flowing flux as it is exposed to the high temperature heat of the reflow, resulting in stress, such as chemical stress and heat stress, caused by the flux. Consequently, peeling between the metal wiring and resin film can occur after the reflow step, which may cause deterioration in reliability. For a semiconductor bump that has an electrode formed from a resin film, good contact between the resin composition and the metal wiring is a very important factor. In recent years, in particular, copper has been in wider use as material for metal wiring from the viewpoint of cost and electric characteristics and accordingly, improved contact with copper has become a very important issue. Furthermore, lead free solder, which does not contain lead, has been in wider use in recent years from the viewpoint of environment protection, but lead free solder generally has a high melting point and requires a high reflow temperature, and accordingly, resin films in semiconductors are now required to realize better contact to resist such high temperatures.

Some studies have proposed the use of a positive type photoresist composition that contains a triazole compound, a compound having a heterocyclic ring, in order to improve the contact with copper (see, for example, Patent document 1). Other studies have proposed the use of a positive type photosensitive resin composition having a nitrogen-containing compound in order to stabilize the sensitivity for an extended period of time after light exposure in the pattern formation step (see, for example, Patent document 2).

In addition, still other studies have proposed the use of a positive type photosensitive resin composition containing a heterocyclic compound in the form of a salt that acts as a thermal acid generator in order to develop good film characteristics even when the heat treatment temperature is as low as 300° C. or less (see, for example, Patent documents 3 to 5).

### PRIOR ART DOCUMENTS

### Patent Documents

Patent document 1: Japanese Unexamined Patent Publication (Kokai) No. 2014-178471
Patent document 2: Japanese Unexamined Patent Publication (Kokai) No. 2007-187710
Patent document 3: Japanese Unexamined Patent Publication (Kokai) No. 2015-26033
Patent document 4: Japanese Unexamined Patent Publication (Kokai) No. 2013-250566
Patent document 5: Japanese Unexamined Patent Publication (Kokai) No. 2011-065167

### SUMMARY OF THE INVENTION

### Problem to be Solved by the Invention

As described above, a typical process for producing a semiconductor apparatus having a bump electrode contains the steps for forming an electrode pad for metal wiring using a pattern resin film produced from a resin composition and applying and reflowing flux thereon. Therefore, strong contact between the resin composition and the metal wiring is required.

However, although Patent document 1 describes the improvement in the resistance to reflow treatment achieved by using a resin composition containing phenol resin and a heterocyclic compound, there still remains the problem of a large decrease in pattern processability resulting from degradation of the photosensitive agent caused by the heterocyclic compound. Patent document 2 discloses that the sensitivity decrease occurring after an extended time after light exposure can be prevented by using a resin composition that contains a polyimide precursor and heterocyclic compound, but there still remains the problem of a large decrease in sensitivity that occurs by the same mechanism as in Patent document 1. Furthermore, Patent documents 3 to 5 disclose the use of a salt formed from a heterocyclic compound and a strong acid with the aim of decreasing the curing temperature for a polybenzoxazole precursor or polyimide precursor, but there is no description about the improvement in contact with metal wiring.

Thus, regarding cured pattern films for semiconductor apparatuses, the present invention aims to provide a photosensitive resin composition that is high in sensitivity and able to realize improved contact between a cured pattern film and metal wiring after the reflow process.

### Means for Solving the Problem

To solve the above problems, the photosensitive resin composition according to the present invention is configured as described below. Specifically, it is a photosensitive resin composition comprising an alkali-soluble resin which contains at least one selected from the group consisting of a resin (a-1) which contains, as primary component, a structure as represented by the undermentioned general formula (1), polyimides (a-2) and copolymers thereof, and compound (c) which contains, as primary component, a structure as represented by the undermentioned general formula (2).

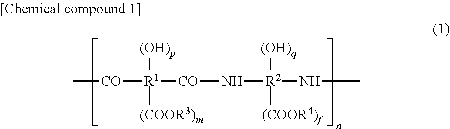

(In general formula (1), R¹ and R² may be identical to or different from each other and each represents a divalent to octavalent organic group having 2 or more carbon atoms. R³ and R⁴ may be identical to or different from each other and each represents either a hydrogen atom or an organic group having 1 to 20 carbon atoms. Here, n is an integer of 10 to 100,000; m and f are independently an integer of 0 to 2; and p and q are independently an integer of 0 to 4; where m+q≠0 and p+q≠0.)

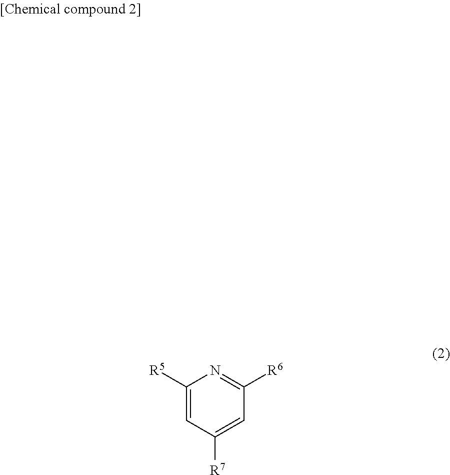

(In general formula (2), R⁵, R⁶, and R⁷ may be identical to or different from each other and each represent either a hydrogen atom or a monovalent organic group having 1 or more carbon atoms, and at least one of R⁵, R⁶, and R⁷ is a monovalent organic group having 1 or more carbon atoms.)

### Advantageous Effects of the Invention

Regarding cured pattern films for semiconductor apparatuses, the present invention provides a positive type photosensitive resin composition that is high in sensitivity and able to realize improved contact between a cured pattern film and metal wiring after a reflow process.

### BRIEF DESCRIPTION OF THE DRAWINGS

FIG. 1 is a schematic cross-sectional diagram of a semiconductor apparatus containing a resin film and metal wiring according to the present invention.

### MODES FOR CARRYING OUT THE INVENTION

Thus, the photosensitive resin composition according to the present invention includes, as described later, an alkali-soluble resin which contains at least one selected from the group consisting of a resin (a-1) which contains, as primary component, a structure as represented by the undermentioned general formula (1), polyimides (a-2) and copolymers thereof, and a compound (c) that contains, as primary component, a structure as represented by the undermentioned general formula (2). The resins (a-1) that contain, as primary component, a structure as represented by general formula (1) and the polyimides (a-2) may be used singly or as a mixture of a plurality thereof or as a copolymer of a plurality thereof.

Such a resin (a-1) that contains, as primary component, a structure as represented by the undermentioned general formula (1) should be one that can form a polymer having an imide ring, oxazole ring, or other cyclic structure when treated by heating or using an appropriate catalyst. Preferable examples include polyimide precursors such as polyamic acid and polyamic acid ester and polybenzoxazole precursors such as polyhydroxyamide. The formation of a cyclic structure serves to dramatically improve the heat resistance and solvent resistance. Here, “being the primary component” means that the n structural units in the structure represented by general formula (1) account for 50 mol % or more of the total number of the structural units in the polymer. The proportion is preferably 70 mol % or more from the viewpoint of maintaining required heat resistance, chemical resistance, and mechanical characteristics, and more preferably 90 mol % or more from the viewpoint of maintaining required heat resistance, chemical resistance, and mechanical characteristics.

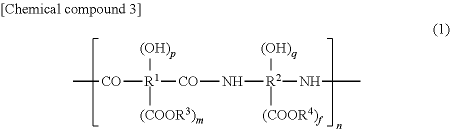

(In general formula (1), R¹ and R² may be identical to or different from each other and each represents a divalent to octavalent organic group having 2 or more carbon atoms. R³ and R⁴ may be identical to or different from each other and each represents either a hydrogen atom or an organic group having 1 to 20 carbon atoms. Here, n is an integer of 10 to 100,000; m and f are independently an integer of 0 to 2; and p and q are independently an integer of 0 to 4; where m+q≠0 and p+q≠0.)

In the aforementioned general formula (1), R¹ is a divalent to octavalent organic group having 2 or more carbon atoms and represents a structural component of the acid. Examples of an acid in which R¹ is divalent include aromatic dicarboxylic acids such as terephthalic acid, isophthalic acid, diphenyl ether dicarboxylic acid, naphthalene dicarboxylic acid, and bis(carboxyphenyl) propane, and aliphatic dicarboxylic acids such as cyclohexane dicarboxylic acid and adipic acid. Examples of an acid in which R¹ is trivalent include tricarboxylic acids such as trimellitic acid and trimesic acid. Examples of an acid in which R¹ is tetravalent include tetracarboxylic acids such as pyromellitic acid, benzophenone tetracarboxylic acid, biphenyl tetracarboxylic acid, and diphenyl ether tetracarboxylic acid. In addition, acids having a hydroxyl group such as hydroxyphthalic acid and hydroxytrimellitic acid may also be useful. Of the acid components containing R¹, two or more thereof may be used together, but it is preferable that 40 mol % or more be accounted for by dicarboxylic acids from the viewpoint of pattern processability.

R¹ preferably contains an aromatic ring from the viewpoint of heat resistance and more preferably contains a divalent or trivalent organic group having 6 to 30 carbon atoms from the viewpoint of pattern processability. Specific examples include those in which the part of R¹(COOR³)ₘ(OH)ₚ in general formula (1) is phenylene (—C₆H₄—), divalent biphenyl (—C₆H₄C₆H₄—), divalent diphenyl ether (—C₆H₄OC₆H₄—), divalent diphenyl hexafluoropropane (—C₆H₄C(CF₃)₂C₆H₄—), divalent diphenyl propane (—C₆H₄C(CH₃)₂C₆H₄—), or divalent diphenyl sulfone (—C₆H₄SO₂C₆H₄—), in which two carboxyl groups may be substituted. The structures given below may also work effectively although the invention is not limited thereto.

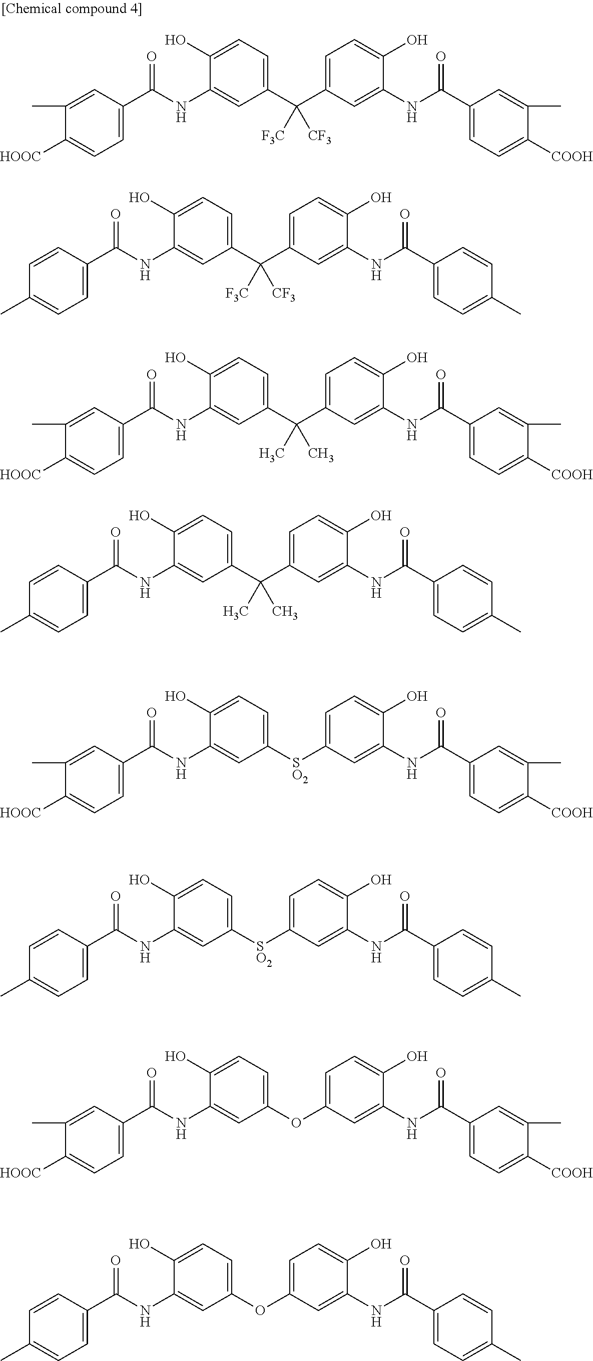

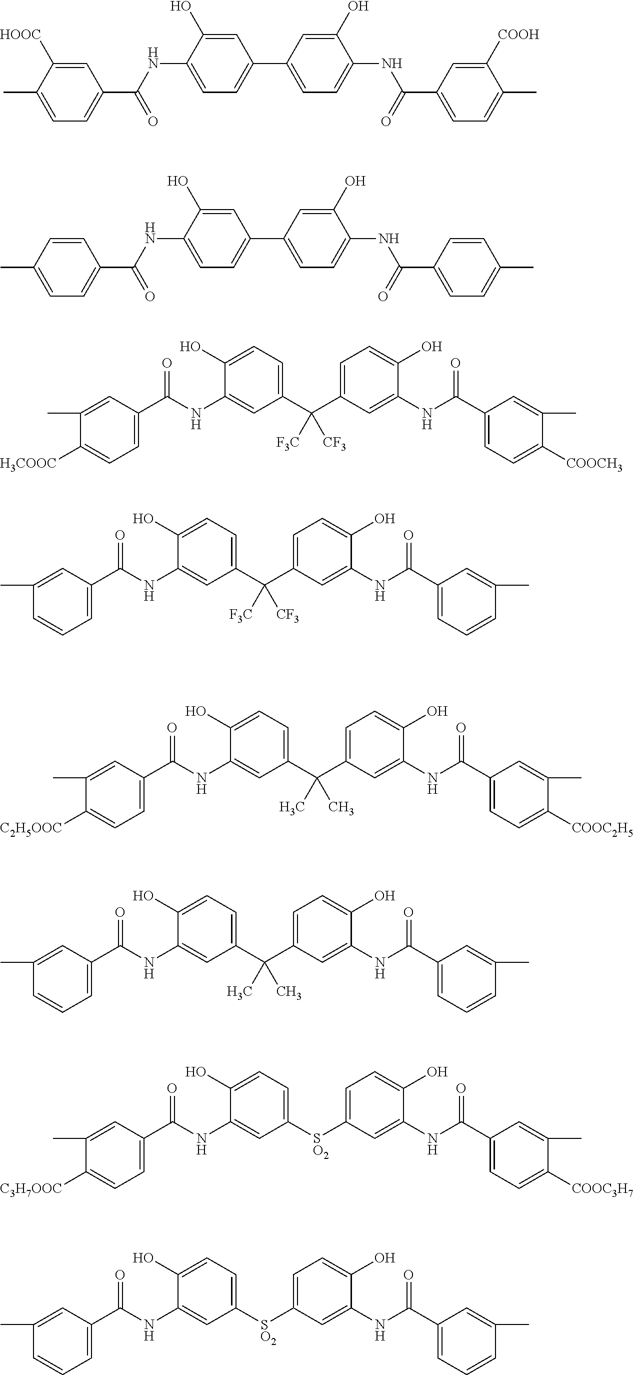

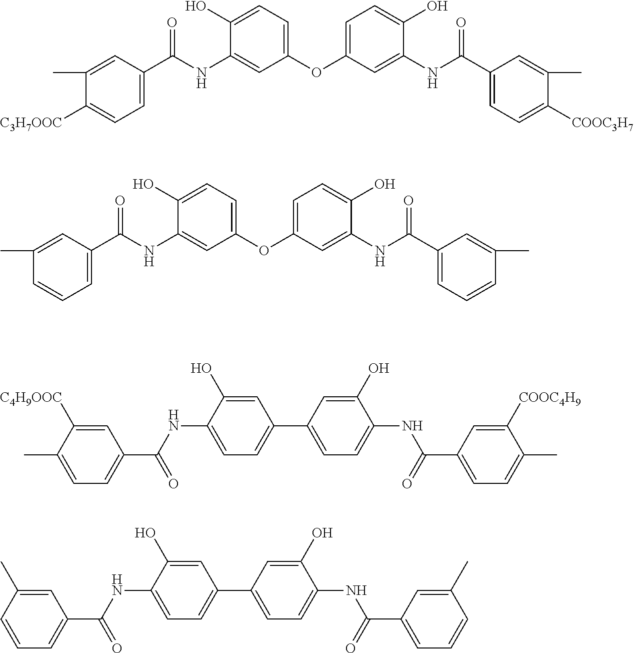

In general formula (1), R² is a divalent to octavalent organic group having 2 or more carbon atoms and represents a structural component of a diamine. It preferably has an aromatic ring from the viewpoint of the heat resistance of the resin to be obtained. Specific examples of a diamine containing R² include compounds containing a fluorine atom such as bis(amino-hydroxy-phenyl) hexafluoropropane, compounds free of a fluorine atom such as diaminodihydroxy pyrimidine, diaminodihydroxy pyridine, hydroxy-diamino-pyrimidine, diaminophenol, dihydroxy benzidine, diaminobenzoic acid, diaminoterephthalic acid, and those in which the part of R²(COOR⁴)_{f}(OH)_{q} in general formula (1) is a structure as given below, although the invention is not limited thereto. Two or more of these diamines may be used together.

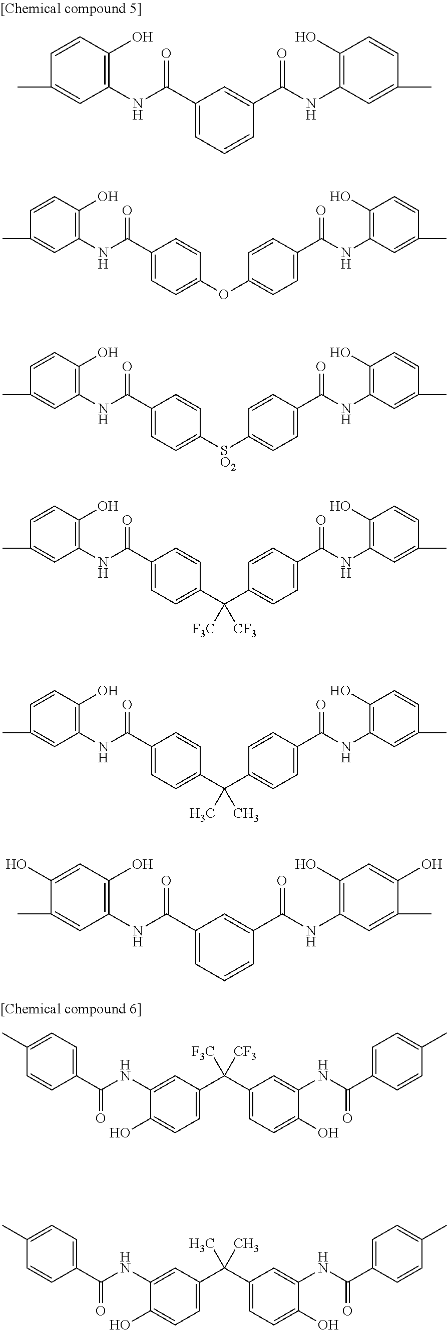

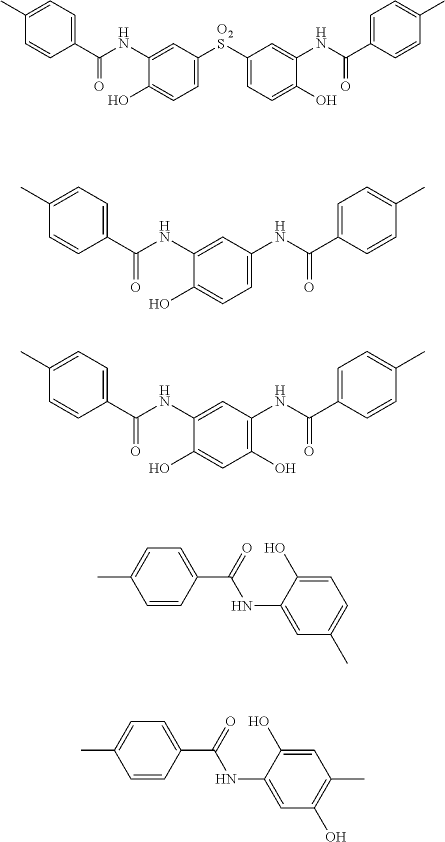

In the structures represented by general formula (1), the aforementioned diamines may be replaced with other diamines or copolymerized with other diamines. Examples of such other diamines include phenylene diamine, diaminodiphenyl ether, aminophenoxy benzene, diaminodiphenyl methane, diaminodiphenyl sulfone, bis(trifluoromethyl) benzidine, bis(aminophenoxyphenyl) propane, and bis(aminophenoxyphenyl) sulfone, in which at least part of the hydrogen atoms in the aromatic rings may be replaced with alkyl groups or halogen atoms, as well as aliphatic compounds such as cyclohexyl diamine, methylene biscyclohexyl amine, and hexamethylene diamine. The residue of such other diamines preferably accounts for 1 to 40 mol % of the total quantity of diamine residues from the viewpoint of solubility in alkali developers.

R³ and R⁴ in general formula (1) may be identical to or different from each other and each represents either a hydrogen atom or a monovalent organic group having 1 to 20 carbon atoms. R³ and R⁴ are each preferably an organic group from the viewpoint of the solution stability of the positive type photosensitive resin composition to be obtained and preferably a hydrogen atom from the viewpoint of the solubility in an aqueous alkali solution. For the present invention, hydrogen atoms and organic groups may coexist. The rate of dissolution in an aqueous alkali solution changes depending on the numbers of hydrogen atoms and organic groups in R³ and R⁴ and therefore, a photosensitive resin composition with a moderate dissolution rate can be obtained by adjusting them. It is preferable for hydrogen atoms to account for 10 to 90 mol % in both R³ and R⁴. If both R³ and R⁴ have 20 or less carbon atoms, a required solubility in an alkali aqueous solution can be maintained. Accordingly, R³ and R⁴ preferably contain at least one hydrocarbon group having 1 to 16 carbon atoms and the all other sites are preferably occupied by hydrogen atoms.

Furthermore, m and fin general formula (1) each represent the number of carboxyl groups or ester groups, and they are independently an integer of 0 to 2. From the viewpoint of pattern processability, m and f are preferably 0. In general formula (1), p and q are each independently an integer of 0 to 4 and meet the relations of m+q≠0 and p+q≠0. It is necessary that m+q≠0 in order to realize the curing of the resin composition through cyclization by heat treatment to ensure improved heat resistance and mechanical characteristics. It is necessary that p+q≠0 from the viewpoint of the solubility in an aqueous alkali solution.

In general formula (1), n represents the number of repetitions of the structural unit of the resin and it is preferably an integer of 10 to 100,000. If n is 10 or more, the resin will not be excessively high in the solubility in an aqueous alkali solution, and a desirable contrast will be realized between the exposed regions and unexposed portions, serving for the formation of the intended pattern. If n is 100,000 or less, the resin will be prevented from decreasing in the solubility in an aqueous alkali solution to ensure that the intended pattern will be formed by dissolving the exposed regions. From the viewpoint of the solubility in an aqueous alkali solution, n is preferably 1,000 or less and more preferably 100 or less. From the viewpoint of improving the elongation percentage, furthermore, n is preferably 20 or more.

For a resin containing a structure as represented by general formula (1) as primary component, the value of n in general formula (1) can be calculated easy from its weight average molecular weight (Mw) measured by gel permeation chromatography (GPC), light scattering, X-ray small angle scattering, etc.

To improve the adhesiveness to the substrate, furthermore, R¹ and/or R² in general formula (1) may be copolymerized with an aliphatic group having a siloxane structure as long as an undesirable decrease in heat resistance will not occur. Specific examples include diamine components such as bis(3-aminopropyl) tetramethyl disiloxane and bis(p-amino-phenyl) octamethyl pentasiloxane, which may be copolymerized to 1 to 10 mol %.

In a resin having a structure as represented by general formula (1) as primary component, the chain end may be reacted with an end capping agent. The rate of dissolution of the resin in an aqueous alkali solution can be controlled in a preferable range by capping the chain end of the resin with a monoamine, anhydride, acid chloride, monocarboxylic acid, etc., containing functional groups such as hydroxyl groups, carboxyl groups, sulfonic acid groups, thiol groups, vinyl groups, ethynyl groups, allyl groups, etc. Such end capping agents as monoamine, acid anhydride, acid chloride, and monocarboxylic acid preferably account for 5 to 50 mol % of the total quantity of amine components.

End capping agents introduced in a resin can be detected easily by such methods as described below. A resin containing an end capping agent may be dissolved in, for instance, an acidic solution to decompose it into the amine components and acid anhydride components, that is, the constituent units of the resin, and then the end capping agent can be detected easily from observations made by gas chromatography (GC) or NMR spectroscopy. In another method, detection can be carried out by subjecting the resin containing an end capping agent directly to pyrolysis gas chromatograph (PGC), infrared spectroscopy, or ¹³C-NMR infrared spectroscopy.

A resin having a structure as represented by general formula (1) as primary component can be synthesized by the method described below. In the case where the resin having a structure as represented by general formula (1) as primary component is a polyamic acid or polyamic acid ester, the available production methods include, for example, a method in which a tetracarboxylic acid dianhydride, a diamine compound, and a monoamino compound used for end capping are reacted at a low temperature, a method in which a diester is obtained from a tetracarboxylic acid dianhydride and an alcohol, followed by its reaction with a diamine and a monoamino compound in the presence of a condensation agent, and a method in which a diester is obtained from a tetracarboxylic acid dianhydride and an alcohol, followed by the conversion of the remaining dicarboxylic acid into an acid chloride and its reaction with a diamine compound and a monoamino compound. In the case where the resin having a structure as represented by general formula (1) as primary component is a polyhydroxyamide, a useful method is to perform condensation reaction of a bisaminophenol compound with a dicarboxylic acid and a monoamino compound. Specifically, available methods include a method in which an acid is reacted with a dehydration condensation agent such as dicyclohexyl carbodiimide (DCC), followed by adding a bisaminophenol compound and a monoamino compound, and a method in which a tertiary amine such as pyridine is added to a solution of a bisaminophenol compound and a monoamino compound, followed by dropping a solution of a dicarboxylic dichloride.

After polymerization by a method as described above, the resulting resin having a structure as represented by general formula (1) as primary component is preferably isolated by putting it in a large amount of water or a liquid mixture of methanol and water for precipitation, followed by filtering and drying. This precipitation step removes oligomer components, such as dimmers and trimers, and unreacted monomers, serving to provide a heat-cured product with improved film characteristics.

The polyimide (a-2) according to the present invention is obtained by converting a polyimide precursor into a polymer with an imide ring by performing heat treatment or using an appropriate catalyst. The formation of a cyclic structure serves to dramatically improve the heat resistance and solvent resistance. The polyimide (a-2) has a structural unit as represented by general formula (3) given below.

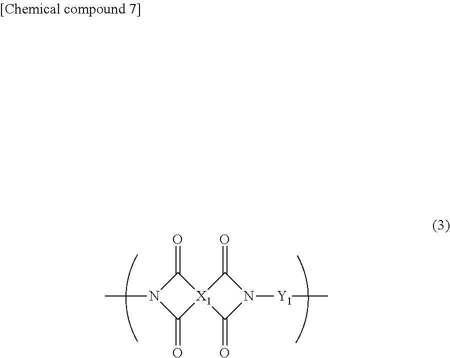

In general formula (3), Y₁ represents an aromatic diamine residue having 1 to 4 aromatic rings. Preferable diamine residues that can constitute Y₁ include divalent residues of the compounds listed below: diamines containing a hydroxyl group such as bis(3-amino-4-hydroxyphenyl) hexafluoropropane, bis(3-amino-4-hydroxyphenyl) sulfone, bis(3-amino-4-hydroxyphenyl) propane, bis(3-amino-4-hydroxyphenyl) methylene, bis(3-amino-4-hydroxyphenyl) ether, bis(3-amino-4-hydroxy) biphenyl, and bis(3-amino-4-hydroxyphenyl) fluorene; diamines containing a sulfonic acid such as 3-sulfonic acid-4,4′-diaminodiphenyl ether; diamines containing a thiol group such as dimercaptophenylene diamine; aromatic diamines such as 3,4′-diaminodiphenyl ether, 4,4′-diaminodiphenyl ether, 3,4′-diaminodiphenyl methane, 4,4′-diaminodiphenyl methane, 3,4′-diaminodiphenyl sulfone, 4,4′-diaminodiphenyl sulfone, 3,4′-diaminodiphenyl sulfide, 4,4′-diaminodiphenyl sulfide, 1,4-bis(4-aminophenoxy) benzene, benzine, m-phenylene diamine, p-phenylene diamine, bis(4-aminophenoxy phenyl) sulfone, bis(3-aminophenoxy phenyl) sulfone, bis(4-aminophenoxy) biphenyl, bis{4-(4-aminophenoxy) phenyl} ether, 1,4-bis(4-aminophenoxy) benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, and 2,2′-bis(trifluoromethyl)-4,4′-diaminobiphenyl; in which part of the hydrogen atoms on the aromatic ring may be substituted by an alkyl group having 1 to 10 carbon atoms, fluoroalkyl group, or halogen atom. These diamines may be used in their original form or in the form of a corresponding diisocyanate compound or trimethylsilylated diamine. It may also be effective to use two or more of these diamine components in combination.

Any polyimide (a-2) used for the present invention has a structural unit as represented by general formula (4) given below.

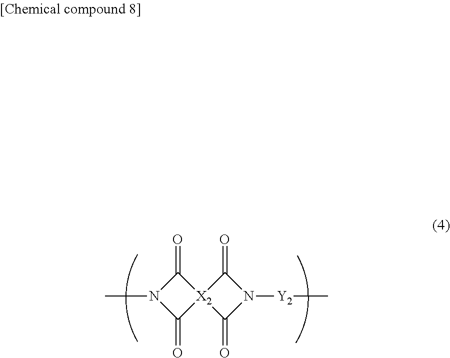

Y₂ in general formula (4) represents a diamine residue having a backbone chain that contains at least two or more alkylene glycol units. It is preferably a diamine compound residue containing a total of two or more of ethylene glycol chains and/or propylene glycol chains in one molecule, more preferably a diamine compound residue having a structure without an aromatic ring.

Examples of a diamine containing both an ethylene glycol chain and a propylene glycol chain include Jeffamine KH-511, Jeffamine ED-600, Jeffamine ED-900, and Jeffamine ED-2003, and examples of a diamine containing an ethylene glycol chain include Jeffamine EDR-148 and Jeffamine EDR-176 (all trade names and manufactured by Huntsman Corporation), although the present invention is not limited thereto.

For a polyimide (a-2), X₁ in general formula (3) represents a tetracarboxylic acid residue having 1 to 4 aromatic rings. X₂ in general formula (4) represents a tetracarboxylic acid residue having 1 to 4 aromatic rings. X₁ and X₂ may be identical to or different from each other and preferred examples of their structures include those of pyromellitic acid, 3,3′,4,4′-biphenyl tetracarboxylic acid, 2,3,3′,4′-biphenyl tetracarboxylic acid, 2,2′,3,3′-biphenyl tetracarboxylic acid, 3,3′,4,4′-benzophenone tetracarboxylic acid, 2,2′,3,3′-benzophenone tetracarboxylic acid, 2,2-bis(3,4-dicarboxyphenyl) hexafluoropropane, 2,2-bis(2,3-dicarboxyphenyl) hexafluoropropane, 1,1-bis(3,4-dicarboxyphenyl) ethane, 1,1-bis(2,3-dicarboxyphenyl) ethane, bis(3,4-dicarboxyphenyl) methane, bis(2,3-dicarboxyphenyl) methane, bis(3,4-dicarboxyphenyl) sulfone, bis(3,4-dicarboxyphenyl) ether, 1,2,5,6-naphthalene tetracarboxylic acid, 2,3,6,7-naphthalene tetracarboxylic acid, 2,3,5,6-pyridine tetracarboxylic acid, 3,4,9,10-perylene tetracarboxylic acid, and other aromatic tetracarboxylic acids that are deprived of their carboxyl groups or in which part of their hydrogen atoms are replaced with 1 to 4 of alkyl groups having 1 to 20 carbon atoms, fluoroalkyl groups, alkoxyl groups, ester groups, nitro groups, cyano groups, fluorine atoms, chlorine atoms.

Any polyimide (a-2) used for the present invention can be obtained by reacting a tetracarboxylic acid to form a tetracarboxylic acid residue as represented by X₁ or X₂ given above with a diamine to form a diamine residue as represented by Y₁ or Y₂ given above to provide a polyamic acid and heating it or chemically treating it with an acid or a base to carry out dehydrative cyclization.

A polyimide (a-2) used for the present invention may partly remain uncyclized or may be fully cyclized and preferably has an imidization rate of 85% or more, more preferably 90% or more. An imidization rate of 85% or more serves to prevent shrinkage and warp of the film from being resulting from the dehydrative cyclization during the thermal imidization step.

A polyimide (a-2) used for the present invention may be composed only of structural units as represented by general formula (3) or general formula (4) or may be a copolymer or mixture with other structural units, but the ratio between the structural unit represented by general formula (3) and the structural unit represented by general formula (4) is preferably 30:70 to 90:10, more preferably 50:50 to 90:10, still more preferably 60:40 to 80:20. If the structural unit represented by general formula (3) is in this proportional range, it serves to realize an alkali solubility that allows the positive type photosensitive resin composition to perform its function. If the structural unit represented by general formula (4) is in this proportional range, it serves to ensure a low degree of warp, high sensitivity, and large elongation percentage. The portions of the structural units represented by general formula (3) or general formula (4) preferably account for 50 mass % or more, more preferably 70 mass % or more, of the entire resin.

A polyimide (a-2) used for the present invention preferably contains a fluorine atom in its structural unit. Such a fluorine atom acts to make the film surface water-repellent to prevent the liquid from penetrating through the surface during the alkali development step. In the component (a-2), such a fluorine atom preferably accounts for 10 mass % or more, and from the viewpoint of maintaining a required solubility in an aqueous alkali solution, it accounts for 20 mass % or less.

It may be copolymerized with an aliphatic group having a siloxane structure with aim of improving the contact with the substrate. Specific examples include diamine components such as bis(3-aminopropyl) tetramethyl disiloxane and bis(p-aminophenyl) octamethyl pentasiloxane.

To improve the storage stability of the resin composition, the backbone chain end of the resin of the component (a-2) is preferably capped with an end capping agent such as a monoamine, acid anhydride, monocarboxylic acid, monoacid chloride compound, and monoactive ester compound.

Acid anhydrides, monocarboxylic acids, monoacid chloride compounds, and monoactive ester compounds that can be used as an end capping agent include anhydrides such as phthalic anhydride, maleic anhydride, nadic anhydride, cyclohexanedicarboxylic anhydride, and 3-hydroxyphthalic anhydride; monocarboxylic acids such as 2-carboxyphenol, 3-carboxyphenol, 4-carboxyphenol, 2-carboxythiophenol, 3-carboxythiophenol, 4-carboxythiophenol, 1-hydroxy-8-carboxynaphthalene, 1-hydroxy-7-carboxynaphthalene, 1-hydroxy-6-carboxynaphthalene, 1-hydroxy-5-carboxynaphthalene, 1-hydroxy-4-carboxynaphthalene, 1-hydroxy-3-carboxynaphthalene, 1-hydroxy-2-carboxynaphthalene, 1-mercapto-8-carboxynaphthalene, 1-mercapto-7-carboxynaphthalene, 1-mercapto-6-carboxynaphthalene, 1-mercapto-5-carboxynaphthalene, 1-mercapto-4-carboxynaphthalene, 1-mercapto-3-carboxynaphthalene, 1-mercapto-2-carboxynaphthalene, 2-carboxybenzene sulfonic acid, 3-carboxybenzene sulfonic acid, 4-carboxybenzene sulfonic acid, 2-ethynyl benzoic acid, 3-ethynyl benzoic acid, 4-ethynyl benzoic acid, 2,4-diethynyl benzoic acid, 2,5-diethynyl benzoic acid, 2,6-diethynyl benzoic acid, 3,4-diethynyl benzoic acid, 3,5-diethynyl benzoic acid, 2-ethynyl-1-naphthoic acid, 3-ethynyl-1-naphthoic acid, 4-ethynyl-1-naphthoic acid, 5-ethynyl-1-naphthoic acid, 6-ethynyl-1-naphthoic acid, 7-ethynyl-1-naphthoic acid, 8-ethynyl-1-naphthoic acid, 3-ethynyl-2-naphthoic acid, 4-ethynyl-2-naphthoic acid, 5-ethynyl-2-naphthoic acid, 6-ethynyl-2-naphthoic acid, 7-ethynyl-2-naphthoic acid, and 8-ethynyl-2-naphthoic acid; monoacid chloride compounds resulting from acid chloridation of the carboxyl group in the above compounds; monoacid chloride compounds resulting from acid chloridation of only the monocarboxyl group in a dicarboxylic acid such as terephthalic acid, phthalic acid, maleic acid, cyclohexanedicarboxylic acid, 3-hydroxyphthalic acid, 5-norbornene-2,3-dicarboxylic acid, 1,2-dicarboxynaphthalene, 1,3-dicarboxynaphthalene, 1,4-dicarboxynaphthalene, 1,5-dicarboxynaphthalene, 1,6-dicarboxynaphthalene, 1,7-dicarboxynaphthalene, 1,8-dicarboxynaphthalene, 2,3-dicarboxynaphthalene, 2,6-dicarboxynaphthalene, and 2,7-dicarboxynaphthalene; and active ester compounds resulting from reaction of a monoacid chloride compound with N-hydroxybenzotriazole, N-hydroxy-5-norbornene-2,3-dicarboxyimide, or the like.

Of these, preferable ones include acid anhydrides such as phthalic anhydride, maleic anhydride, nadic anhydride, cyclohexanedicarboxylic anhydride, and 3-hydroxyphthalic anhydride; monocarboxylic acids such as 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene, 1-mercapto-5-carboxynaphthalene, 3-carboxybenzene sulfonic acid, 4-carboxybenzene sulfonic acid, 3-ethynyl benzoic acid, 4-ethynyl benzoic acid, 3,4-diethynyl benzoic acid, and 3,5-diethynyl benzoic acid; monoacid chloride compounds resulting from acid chloridation of the carboxyl groups thereof; monoacid chloride compounds resulting from acid chloridation of only the monocarboxyl groups in dicarboxylic acids such as terephthalic acid, phthalic acid, maleic acid, cyclohexanedicarboxylic acid, 1,5-dicarboxynaphthalene, 1,6-dicarboxynaphthalene, 1,7-dicarboxynaphthalene, and 2,6-dicarboxynaphthalene; and active ester compounds resulting from reaction of a monoacid chloride compound with N-hydroxybenzotriazole, N-hydroxy-5-norbornene-2,3-dicarboxyimide, or the like.

It is more preferable to use a monoamine as the end capping agent, and preferable monoamine compounds include aniline, 2-ethynyl aniline, 3-ethynyl aniline, 4-ethynyl aniline, 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzene sulfonic acid, 3-aminobenzene sulfonic acid, 4-aminobenzene sulfonic acid, 3-amino-4,6-dihydroxy pyrimidine, 2-aminophenol, 3-aminophenol, 4-aminophenol, 2-aminothiophenol, 3-aminothiophenol, and 4-aminothiophenol. Two or more thereof may be used together, and a plurality of end capping agents may be reacted to introduce a plurality of different end groups.

For any polyimide (a-2) used for the present invention, Y₂ in the structural unit represented by general formula (4), i.e., a diamine residue having alkylene glycol units in the backbone chain, is preferably one having a structure as represented by general formula (5) given below. The use of a diamine residue having a structure as represented by general formula (5) is preferable because it can realize a low elastic modulus to ensure little warp, a high flexibility to ensure an improved elongation percentage, and a high heat resistance.

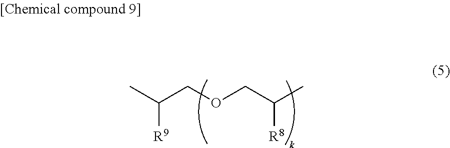

(In general formula (5), R⁸ and R⁹ each represent a hydrogen atom or an alkyl group having 1 to 20 carbon atoms, and the plurality of R⁸ groups in one residue compound may be identical to or different from each other; and k is an integer of 2 to 50.)

The positive type photosensitive resin composition according to the present invention may contain a phenol resin (b).

Such a phenol resin (b) can be produced by carrying out condensation polymerization of a phenol and an aldehyde by a generally known method. Two or more phenol resins may be contained in combination.

Preferable examples of the phenol include phenol, o-cresol, m-cresol, p-cresol, 2,3-xylenol, 2,5-xylenol, 3,4-xylenol, 3,5-xylenol, 2,3,5-trimethyl phenol, and 3,4,5-trimethyl phenol. Particularly preferable ones are phenol, m-cresol, p-cresol, 2,3-xylenol, 2,5-xylenol, 3,4-xylenol, 3,5-xylenol, and 2,3,5-trimethyl phenol. Two or more of these phenols may be used in combination. From the viewpoint of the solubility in alkali developers, m-cresol is preferable and the combination of m-cresol and p-cresol is also preferable. Thus, it is preferable to contain a resin having a phenolic hydroxyl group, specifically a cresol novolac resin containing m-cresol residue or a combination of m-cresol residue and p-cresol residue. In this case, the molar ratio between the m-cresol residue and p-cresol residue in the cresol novolac resin (m-cresol residue vs. p-cresol residue, m/p) is preferably 1.8 or more. A ratio in this range ensures a moderate solubility in an alkali developer and a high sensitivity. It is more preferably 4 or more.

Preferable examples of the aforementioned aldehyde include formalin, para-formaldehyde, acetaldehyde, benzaldehyde, hydroxybenzaldehyde, chloroacetaldehyde, and salicyl aldehyde. Of these, formalin is particularly preferable. Two or more of these aldehydes may be used in combination. From the viewpoint of pattern processability, the quantity of these aldehydes is preferably 0.6 mole or more, more preferably 0.7 mole or more, and preferably 3.0 moles or less, more preferably 1.5 moles or less, per mole of the phenols used.

Commonly, an acidic catalyst is used in the reaction for condensation polymerization of a phenol and an aldehyde. Examples of the acidic catalyst include, for example, hydrochloric acid, nitric acid, sulfuric acid, formic acid, oxalic acid, acetic acid, and p-toluene sulfonic acid. The quantity of these acidic catalysts is commonly 1×10⁻⁵ to 5×10⁻¹ moles per mole of the phenols used. For the condensation polymerization reaction, water is commonly used as reaction medium, but a hydrophilic solvent or a lipophilic solvent is used in the case where the reaction system becomes heterogeneous at an initial stage of the reaction. Examples of the hydrophilic solvent include, for example, alcohols such as methanol, ethanol, propanol, butanol, and propylene glycol monomethyl ether; and cyclic ethers such as tetrahydrofuran and dioxane. Examples of the lipophilic solvent include ketones such as methyl ethyl ketone, methyl isobutyl ketone, and 2-heptanone. The quantity of these reaction mediums is commonly 20 to 1,000 parts by mass relative to 100 parts by mass of the reaction material.

The reaction temperature for condensation polymerization is commonly 10° C. to 200° C., though it may be adjusted appropriately depending on the reactivity of the material. There are some useful reaction methods for the condensation polymerization, including a method in which a phenol, aldehyde, acidic catalyst, etc., are fed together and subjected to reaction and a method in which a phenol, aldehyde, etc., are added one by one in the presence of an acidic catalyst as the reaction progresses, from which an appropriate one may be selected. To remove unreacted materials, acidic catalyst, reaction medium, etc., that remain in the system after the end of the condensation polymerization reaction, the reaction temperature is commonly increased to 130° C. to 230° C. and volatile matters are removed under reduced pressure, followed by collecting a resin component that contains a phenolic hydroxyl group.

For the present invention, the phenol resin (b) preferably has a polystyrene based weight average molecular weight (Mw) of 2,000 or more and 15,000 or less, more preferably 3,000 or more and 10,000 or less. Its quantity in this range serves to ensure a decreased pattern size variation after curing while maintaining a high sensitivity and high resolution.

From the viewpoint of pattern processability, the quantities of the alkali-soluble resin which contains at least one selected from the group consisting of the resin (a-1) which contains, as primary component, a structure as represented by the aforementioned general formula (1), polyimides (a-2) and copolymers thereof, and the phenol resin (b) preferably meet the relation ((a-1)+(a-2))/(b)=95/5 to 5/95 (mass ratio). From the viewpoint of the contact with metal wiring after flux treatment, it is more preferable for them to meet the relation ((a-1)+(a-2))/(b)=90/10 to 45/55 by mass.

For the present invention, examples of the phenol resin (b) include resol resin and novolac resin, of which novolac resin is preferable from the viewpoint of ensuring a high sensitivity and storage stability.

In addition, the photosensitive resin composition according to the present invention contains a compound (c) that has, as primary component, a structure as represented by general formula (2). In general, nitrogen-containing compounds are contained as impurities in a photosensitive resin precursor composition. However, the contact with copper and pattern processability will improve if a compound (c) that has, as primary component, a structure as represented by general formula (2) is contained.

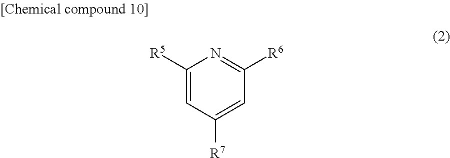

(In general formula (2) given above, R⁵, R⁶, and R⁷ may be identical to or different from each other and each represent either a hydrogen atom or a monovalent organic group having 1 or more carbon atoms, and at least one of R⁵, R⁶, and R⁷ is a monovalent organic group having 1 or more carbon atoms.)

In general formula (2), R⁵, R⁶, and R⁷ may be identical to or different from each other and each represent either a hydrogen atom or a monovalent organic group having 1 or more carbon atoms, and at least one of R⁵, R⁶, and R⁷ is a monovalent organic group having 1 or more carbon atoms. A heterocyclic compound containing a nitrogen atom generally acts to deactivate photosensitive agents and reduce the pattern processability, but the reduction in sensitivity can be prevented if at least one of R⁵, R⁶, and R⁷ is a monovalent organic group having 1 or more carbon atoms. Specific examples of such compounds as represented by general formula (2) include methylpyridine, ethylpyridine, propylpyridine, butylpyridine, 4-(1-butylpentyl)pyridine, dimethylpyridine, trimethylpyridine, triethylpyridine, phenylpyridine, 2-methyl-4-phenyl-pyridine, 2-methyl-6-phenyl-pyridine, 4-tert-butylpyridine, diphenylpyridine, benzylpyridine, methoxypyridine, butoxypyridine, dimethoxypyridine, 1-methyl-2-pyridone, 4-pyrrolidinopyridine, 1-methyl-4-phenylpyridine, 2-(1-ethylpropyl)pyridine, aminopyridine, and dimethyl aminopyridine, although the present invention is not limited thereto.

From the viewpoint of further improving the contact with copper, the compound (c) having, as primary component, a structure as represented by general formula (2) preferably accounts for 0.01 part by mass or more, more preferably 0.05 part by mass or more, relative to 100 parts by mass of the alkali-soluble resin containing at least one selected from the group consisting of the resin (a-1) having, as primary component, a structure as represented by the aforementioned general formula (1), polyimides (a-2) and copolymers thereof. From the viewpoint of pattern processability, on the other hand, the proportion is preferably 5 parts by mass or less, more preferably 3 parts by mass or less. It is still more preferable to be 0.42 parts by mass or more and 0.68 part by mass or less in order to ensure both good contact with copper and pattern processability.

For the present invention, a quinone diazide compound (d) may be added with the aim of developing photosensitivity. For the quinone diazide compound, 5-naphthoquinone diazide sulfonyl groups and 4-naphthoquinone diazide sulfonyl groups are used favorably. A 4-naphthoquinone diazide sulfonyl ester compound absorbs light in the i-line range of mercury lamps, and therefore, it is suitable for i-line light exposure. A 5-naphthoquinone diazide sulfonyl ester compound absorbs light in a region including the g-line of mercury lamps, and therefore, it is suitable for g-line light exposure. For the present invention, it is preferable to adopt either a 4-naphthoquinone diazide sulfonyl ester compound or a 5-naphthoquinone diazide sulfonyl ester compound depending on the wavelength of the light used for exposure. Furthermore, it is possible to obtain a naphthoquinone diazide sulfonyl ester compound containing both a 4-naphthoquinone diazide sulfonyl group and a 5-naphthoquinone diazide sulfonyl group in one molecule, or it may also be effective to use a mixture of a 4-naphthoquinone diazide sulfonyl ester compound and a 5-naphthoquinone diazide sulfonyl ester compound.

When using a quinone diazide compound with a molecular weight of 1,500 or less, the quinone diazide compound is thermally decomposed to a sufficient degree in the subsequent heat treatment step, leading to a film having required heat resistance, mechanical characteristics, and adhesiveness. If the molecular weight is 300 or more, on the other hand, the decomposition of the quinone diazide is depressed in the heat treatment step after the coating step, allowing a required pattern processability to be maintained. From this point of view, the quinone diazide compound preferably has a molecular weight of 300 to 1,500. It is more preferably 350 to 1,200, and when it is in this range, a film with a high heat resistance, good mechanical characteristics, and high adhesiveness can be produced.

For the positive type photosensitive resin composition according to the present invention, the quinone diazide compound (d) preferably accounts for 1 part by mass or more, more preferably 3 parts by mass or more, relative to 100 parts by mass of the alkali-soluble resin containing at least one selected from the group consisting of the resin (a-1) having, as primary component, a structure as represented by the aforementioned general formula (1), polyimides (a-2) and copolymers thereof, from the viewpoint of allowing the unexposed region to maintain a required film thickness after development. From the viewpoint of pattern processability, on the other hand, the proportion is preferably 50 parts by mass or less, more preferably 40 parts by mass or less.

A quinone diazide compound to be use for the present invention can be synthesized from a specific phenol compound by procedures as described below. For example, a useful procedure is to react 5-naphthoquinonediazide sulfonyl chloride with a phenol compound in the presence of triethyl amine. To synthesize a phenol compound, a useful procedure is to react an α-(hydroxyphenyl) styrene derivative with a multivalent phenol compound in the presence of an acid catalyst.

The positive type photosensitive resin composition according to the present invention may contain a solvent (e). Useful solvents include polar aprotic solvents such as γ-butyrolactone; ethers such as tetrahydrofuran, dioxane, propylene glycol monomethyl ether; dialkylene glycol dialkyl ethers such as dipropylene glycol dimethyl ether, diethylene glycol dimethyl ether, and diethylene glycol ethyl methyl ether; ketones such as acetone, methyl ethyl ketone, diisobutyl ketone, diacetone alcohol, N,N-dimethyl formamide, and N,N-dimethyl acetamide; acetates such as 3-methoxy butyl acetate and ethylene glycol monoethyl ether acetate; esters such as ethyl acetate, propylene glycol monomethyl ether acetate, and ethyl lactate; and aromatic hydrocarbons such as toluene and xylene; which may be used singly or as a mixture thereof.

For the positive type photosensitive resin composition according to the present invention, the solvent (e) preferably accounts for 50 part by mass or more, more preferably 100 parts by mass or more, relative to 100 parts by mass of the alkali-soluble resin containing at least one selected from the group consisting of the resin (a-1) having, as primary component, a structure as represented by the aforementioned general formula (1), polyimides (a-2) and copolymers thereof, from the viewpoint of obtaining a positive type photosensitive resin film having a film thickness that allows the resin film to have a required pattern processability. From the viewpoint of obtaining a resin film having a film thickness that allows it to function as a protection film, it is preferably 2,000 parts by mass or less, more preferably 1,500 parts by mass or less.

The positive type photosensitive resin composition according to the present invention may include a compound (f) containing an alkoxy methyl group. Preferable examples of the compound (f) containing an alkoxy methyl group include those compounds as represented by the undermentioned general formula (6). A compound as represented by general formula (6) has an alkoxy methyl group, and an alkoxy methyl group undergoes crosslinking reaction in the temperature region of 150° C. or more. Accordingly, such a compound, if present, will be crosslinked during the heat treatment step designed to cyclize and cure the polyimide precursor or polybenzoxazole precursor by heating, thus leading to a good patterned shape. Such a compound preferably contains 2 or more alkoxy methyl groups to increase the crosslink density and more preferably contains 4 or more alkoxy methyl groups to increase the crosslink density and further improve the chemical resistance. From the viewpoint of ensuring a reduced pattern size variation after curing, it is preferable to include at least one or more such compounds containing 6 or more alkoxy methyl groups.

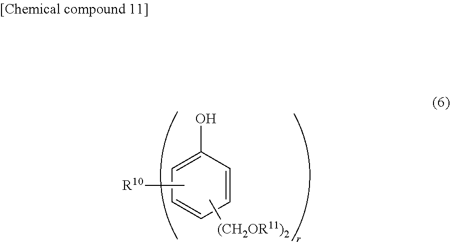

(In general formula (6), R¹⁰ represents a monovalent to decavalent organic group. The R¹¹ groups may be identical to or different from each other and each represent an alkyl group having 1 to 4 carbon atoms; and r is an integer of 1 to 10.)

Specific examples of the compound (f) include the following compounds, although the present invention is not limited thereto. Two or more of them may be contained together.

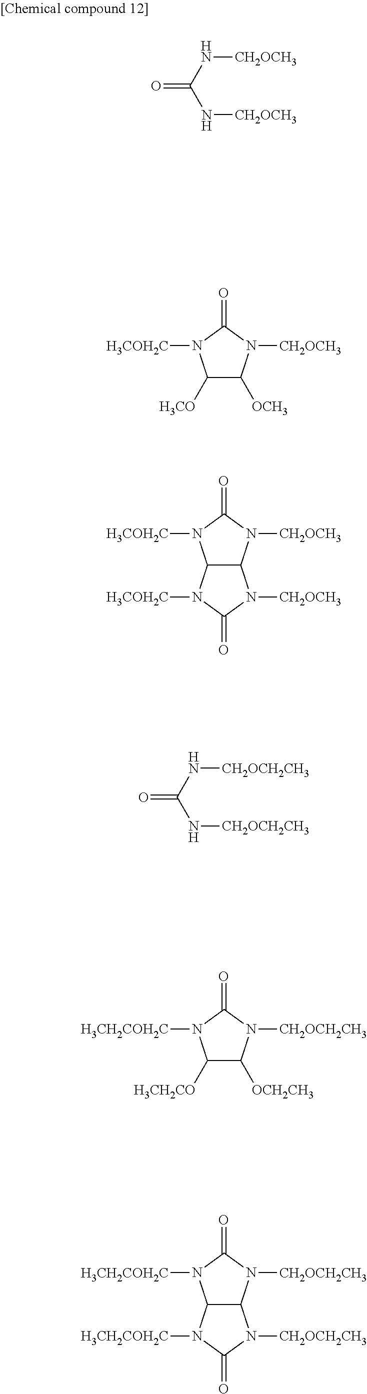

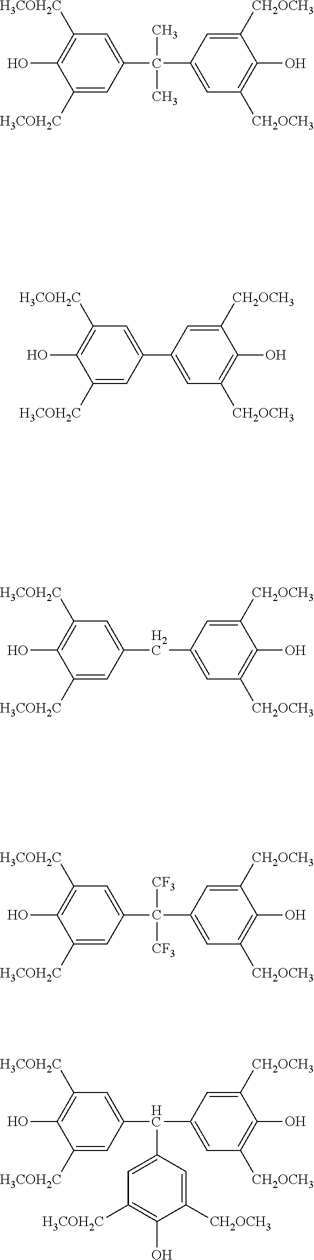

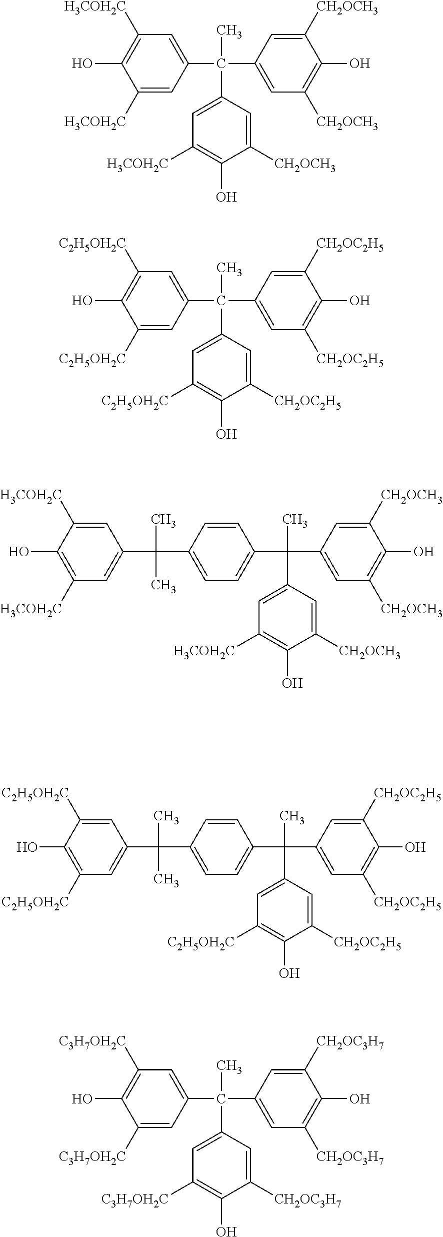

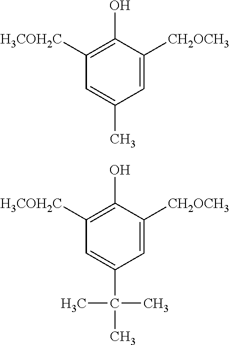

From the viewpoint of increasing the crosslink density and further improving the chemical resistance and mechanical characteristics, the compound (f) preferably accounts for 1 part by mass or more relative to 100 parts by mass of the alkali-soluble resin containing at least one selected from the group consisting of the resin (a-1) having, as primary component, a structure as represented by the aforementioned general formula (1), polyimides (a-2) and copolymers thereof. It is preferably 20 parts by mass or less because cracking can be depressed after the heat treatment step.

The positive type photosensitive resin composition according to the present invention may contain a silane compound (g), which can act to improve the adhesiveness to the substrate. Specific examples of such a silane compound (g) include N-phenylaminoethyl trimethoxysilane, N-phenylaminoethyl triethoxysilane, N-phenylaminopropyl trimethoxysilane, N-phenylaminopropyl triethoxysilane, N-phenylaminobutyl trimethoxysilane, N-phenylaminobutyl triethoxysilane, vinyl trimethoxysilane, vinyl triethoxysilane, vinyl trichlorosilane, vinyl tris-(β-methoxyethoxy)silane, 3-methacryloxypropyl trimethoxysilane, 3-acryloxypropyl trimethoxysilane, p-styryl trimethoxysilane, 3-methacryloxypropyl methyl dimethoxysilane, 3-methacryloxypropyl methyl diethoxysilane, and other silane compounds having a structure as shown below, although the present invention is not limited thereto. Two or more thereof may be contained.

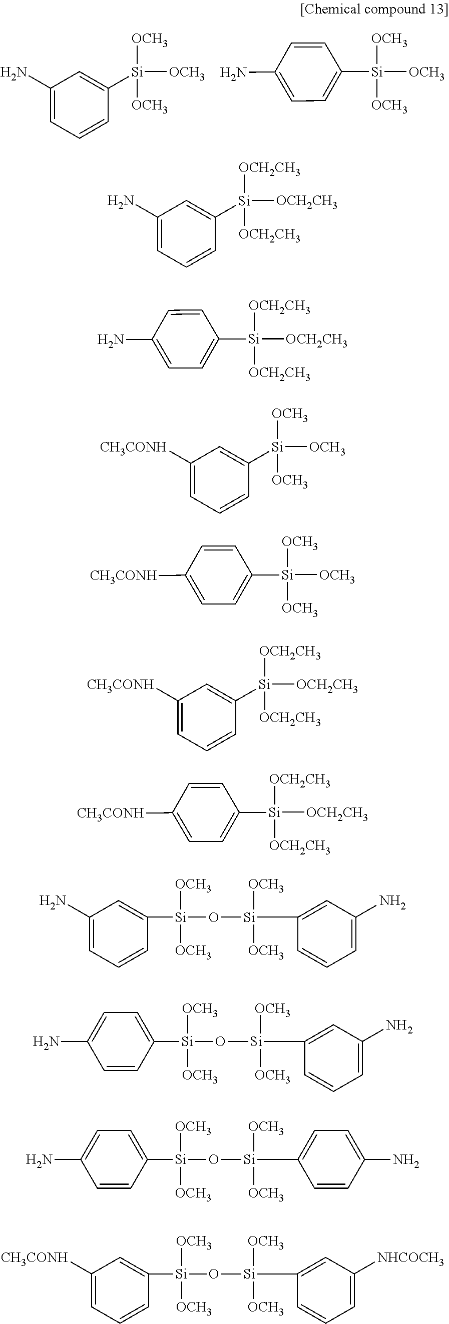

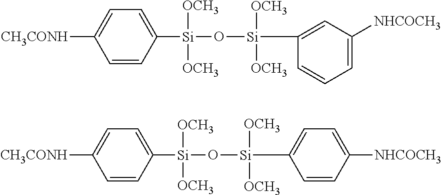

From the viewpoint of working as an adhesion assistant having an adequate effect, the silane compound (g) preferably accounts for 0.01 parts by mass or more relative to 100 parts by mass of the alkali-soluble resin containing at least one selected from the group consisting of the resin (a-1) having, as primary component, a structure as represented by the aforementioned general formula (1), polyimides (a-2) and copolymers thereof. It is preferably 15 parts by mass or less from the viewpoint of allowing the positive type photosensitive resin composition to maintain a required heat resistance.

The positive type photosensitive resin composition according to the present invention may include a compound (h) containing a phenolic hydroxyl group. If such a compound containing a phenolic hydroxyl group is present, the resulting positive photosensitive resin composition will not be dissolved significantly in an alkaline developer before light exposure, but will be easily dissolved in an alkaline developer after light exposure, leading to a decreased film loss during development and easy development in a short time. Particularly preferable compounds for use as such a compound (h) containing a phenolic hydroxyl group include Bis-Z, TekP-4HBPA, TrisP-HAP, TrisP-PA, BisRS-2P, and BisRS-3P (all trade names and available from Honshu Chemical Industry Co., Ltd.), and BIR-PC, BIR-PTBP, and BIR-BIPC-F (all trade names and available from Asahi Organic Chemicals Industry Co., Ltd.).

From the viewpoint of heat resistance and mechanical characteristics, the compound (h) containing a phenolic hydroxyl group preferably accounts for 3 parts by mass or more and 40 parts by mass or less relative to 100 parts by mass of the alkali-soluble resin containing at least one selected from the group consisting of the resin (a-1) having, as primary component, a structure as represented by the aforementioned general formula (1), polyimides (a-2) and copolymers thereof.

With the aim of improving the wettability of the positive type photosensitive resin composition to the substrate, it may contain, as required, esters such as ethyl lactate and propylene glycol monomethyl ether acetate, alcohols such as ethanol, ketones such as cyclohexanone and methyl isobutyl ketone, and/or ethers such as tetrahydrofuran and dioxane. In addition, inorganic particles of silicon dioxide, titanium dioxide, or the like and powder of polyimide or the like may also be contained.

Typical production methods for the positive type photosensitive resin composition according to the present invention are described below. For example, an alkali-soluble resin containing at least one selected from the group consisting of a resin (a-1) having, as primary component, a structure as represented by the aforementioned general formula (1), polyimides (a-2) and copolymers thereof, phenol resin (b), a compound (c) having, as primary component, a structure as represented by general formula (2), a quinone diazide compound (d), a solvent (e), and other components, if necessary, are put in a glass flask or a stainless steel container and dissolved by stirring using a mechanical stirrer or the like, or dissolved using a ultrasonic device, or dissolved by stirring using a planetary stirring and deaerating machine. The composition preferably has a viscosity of 200 to 10,000 mPa·s. It may be filtered through a filter with a pore size of 0.1 to 5 μm to remove foreign objects.

Descried below is a method to produce a heat-resistant pattern resin film from the positive type photosensitive resin composition according to the present invention.

The positive type photosensitive resin composition is spread on a substrate. Useful materials used as the substrate include, but not limited to, silicon wafer, ceramic, gallium arsenide, metal, glass, metal oxide insulation film, silicon nitride, and indium tin oxide (ITO). Useful coating methods include spin coating, spray coating, roll coating, and slit die coating. For the present invention, the spin coating method can serve particularly effectively to realize the intended effect. The coating thickness depends on the coating method used, solid content in the composition, viscosity, and the like, but commonly, coating is performed in such a manner that the film thickness will be 5 to 30 μm after drying. From the viewpoint of the chemical resistance after flux treatment, it is preferably 2 um or more. From the viewpoint of the contact with metal wiring after flux treatment, on the other hand, it is preferably 15 um or less.

Then, the substrate coated with the positive type photosensitive resin composition is dried to provide a photosensitive resin film. Drying is performed using an oven, hot plate, infrared ray, or the like, and preferably continued for 1 minute to several hours in the temperature range of 50° C. to 150° C.

Then, an actinic ray is applied to the photosensitive resin film through a mask of an intended pattern to carry out light exposure. Actinic rays available for the light exposure include ultraviolet ray, visible light, electron beam, and X-ray, of which the i-line (365 nm), h-line (405 nm), and g-line (436 nm) of mercury lamp are preferred for the invention.

To create a pattern on the heat-resistant pattern resin film from the photosensitive resin film, the exposed regions are removed by a developer after the light exposure. Preferable developers include aqueous solutions of alkaline compounds such as aqueous tetramethyl ammonium solution, diethanol amine, diethyl aminoethanol, sodium hydroxide, potassium hydroxide, sodium carbonate, potassium carbonate, trimethyl amine, diethyl amine, methyl amine, dimethyl amine, dimethylaminoethyl acetate, dimethylaminoethanol, dimethylaminoethyl methacrylate, cyclohexyl amine, ethylene diamine, and hexamethylene diamine. In some cases, such aqueous alkali solutions may also contain polar solvents such as N-methyl-2-pyrolidone, N,N-dimethyl formamide, N,N-dimethyl acetamide, dimethyl sulfoxide, γ-butyrolactone, and dimethyl acrylamide; alcohols such as methanol, ethanol and isopropanol; esters such as ethyl lactate and propylene glycol monomethyl ether acetate; and ketones such as cyclopentanone, cyclohexanone, isobutyl ketone, and methyl isobutyl ketone; which may be added singly or as a combination of two or more thereof. Rinsing in water is preferably performed after the development step. Here again, the water used for rinsing may contain an alcohol such as ethanol and isopropyl alcohol, and an ester such as ethyl lactate and propylene glycol monomethyl ether acetate.

After developing the pattern resin film, heating is performed at a temperature of 200° C. to 500° C. to convert it into a heat-resistant cured pattern film. In general, this heat treatment is performed for 5 minutes to 5 hours while raising the temperature stepwise at appropriately selected temperatures or raising it continuously over an appropriately selected temperature range. For example, heat treatment may be performed by maintaining the temperature at 130° C., 200° C., and 350° C. for 30 minutes each, or by raising the temperature linearly over 2 hours from room temperature to 320° C., or by setting a high feeding temperature at 200° C. followed by raising it linearly over 2 hours.

Such heat-resistant cured pattern films produced from the positive type photosensitive resin composition according to the present invention can be used favorably for various applications such as surface protection film layers in semiconductor apparatuses, insulation films used for forming re-wiring layers in semiconductor apparatuses, passivation films for semiconductors, protection films in semiconductor devices, interlaminar insulation films for high density multi-layered wiring, and insulation layers in organic electroluminescent devices.

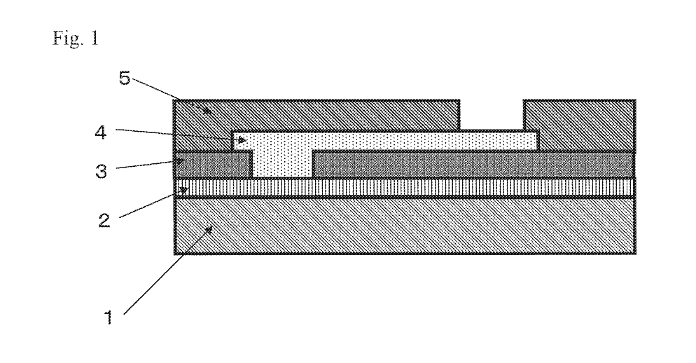

A preferred structure for the present invention is shown in FIG. 1 below.

Generally, a passivation film 2 is formed on a semiconductor device 1. On the passivation film 2, the photosensitive resin composition according to the present invention is spread by spin coating, dried by heating using a hot plate or the like, and patterned by light exposure and development. The patterning of the resin film is followed by a high temperature treatment step, which performs curing to form a resin film (cured pattern film) 3. Metal wiring 4 is formed on the resin film 3 by an appropriate technique such as sputtering, deposition, electroless plating, and electroplating. To protect the metal wiring 4, furthermore, the photosensitive resin composition according to the present invention is spread by spin coating, dried by heating using a hot plate or the like, and patterned by light exposure and development. The patterning of the resin film is followed by a high temperature treatment step, which performs curing to form a resin film (cured pattern film) 5. The formation of the resin films 3 and 5 by the above procedure serves to provide a semiconductor apparatus in which strong contact is realized between the resin films 3 and 5 and between the metal wiring 4 and the resin films 3 and 5.

### EXAMPLES

The present invention will be illustrated below in greater detail with reference to examples etc., but it should be understood that the invention is not construed as being limited thereto. The esterification degree of each quinone diazide compound synthesized and the evaluation of the positive type photosensitive resin composition prepared in each Example were carried out as described below.

### <Method for Measuring the Film Thickness>

Using a Lambda Ace STM-602 apparatus manufactured by Dainippon Screen Mfg. Co., Ltd., the thickness of prebaked film samples and that of developed film samples was measured based on polyimide as reference assuming a refractive index of 1.629.

### <Measurement of Imidization Degree of Polyimide>

To determine the imidization degree of a polyimide (a-2), a N-methyl pyrolidone (NMP) solution with a solid polyimide resin content of 50 mass % was spread by spin coating on a 6 inch silicon wafer and baked for 3 minutes on a hot plate (SKW-636, manufactured by Dainippon Screen Mfg. Co., Ltd.) controlled at 120° C. to prepare a prebaked film with a thickness of 10 μm±1 μm. This film was broken into two and one half was placed on an inert gas oven (INH-21CD, manufactured by Koyo Thermo Systems Co., Ltd.) and heated by raising the temperature over 30 minutes up to a cure temperature of 350° C., followed by performing heat treatment at 350° C. for 60 minutes. Subsequently, the sample was cooled slowly until the inner temperature of the oven lowered below 50° C. to provide a cured film. The resulting cured film (A) and the uncured film (B) were examined using a Fourier-transform infrared spectroscope (FT-720, manufactured by Horiba, Ltd.) to obtain their infrared absorption spectrums. The intensity of the peak near 1377 cm⁻¹ attributable to the C—N stretching vibration of the imide ring was determined for each film sample and the ratio [peak intensity of uncured film (B)/peak intensity of cured film (A)] was assumed to represent the imidization degree.

### <Preparation of Photosensitive Resin Film>

Varnish of a photosensitive resin composition was spread on an 8 inch silicon wafer by spin coating in such a manner that the film thickness T1 (film thickness after coating) would be 8.5 to 9.0 μm after the prebaking step and then prebaked on a hot plate (ACT8 coater/developer, manufactured by Tokyo Electron Ltd.) at 120° C. for 3 minutes to provide a photosensitive resin film.

### <Light Exposure>

A patterned reticle was set on a light exposure machine (NSR2005i9C i-line stepper, manufactured by Nicon) and the photosensitive resin film was exposed to i-line at a strength of 365 nm for a predetermined period of time.

### <Development>

Using an ACT8 developer manufactured by Tokyo Electron Ltd., rotating at 50 rpm, a 2.38 mass % aqueous solution of tetramethyl ammonium hydroxide was sprayed for 10 seconds on the light-exposed film. Then, it was left to stand at 0 rpm for 40 seconds. After shaking off the developer, tetramethyl ammonium hydroxide was sprayed again and the sample was left to stand for 20 seconds. Subsequently, rinsing treatment with water was performed at 400 rpm, and the sample was rotated at 3,000 rpm for 10 seconds to shake off water and dried.

### <Evaluation for Pattern Processability>

In the above exposure and development steps, the exposure time was changed repeatedly to determine the minimum exposure (Eth) required for the developed 50 μm pad pattern to open to 50 μm. A sample is considered to be acceptable in terms of pattern processability if its Eth is 600 mJ/cm² or less, and it is more preferably 400 mJ/cm² or less and still more preferably 300 mJ/cm² or less.

### <Formation of Cured Film by Heat Treatment>

The pattern-processed film prepared above for pattern processability evaluation was heat-treated at 350° C. for 60 minutes in a vertical type curing furnace (VF-1000B, manufactured by Koyo Thermo Systems Co., Ltd.) in a nitrogen atmosphere with an oxygen concentration of 20 ppm or less to provide a cured pattern film.

### <Reflow Treatment>

Tantalum (Ta) was sputtered on an 8 inch silicon wafer to a thickness of 25 nm and then copper was sputtered to a thickness of 100 nm, followed by forming a 3 μm copper layer by electroplating to prepare a copper substrate. A cured pattern film was formed on the copper substrate by the method described above. Flux (WS9160, manufactured by Alent Japan Company) was spread on the cured pattern film formed the copper substrate and the patterned wafer was subjected to reflow treatment in a reflow furnace (RN-S ANUR820iN, manufactured by Panasonic Industrial Devices SUNX Tatsuno Co., Ltd.). The reflow treatment was carried out under conditions with an oxygen concentration 1,000 ppm or less and the heater temperature and conveyor speed were adjusted so that the wafer would be heated at 270° C. for 60 seconds or more. After the treatment, the sample was washed with water at 50° C. and air-dried, followed by further drying for 1 hour or more in an atmosphere at 23° C. and 50% RH.

<Evaluation for Contact with Copper>

The cured pattern film after undergoing reflow treatment was subjected to peeling test. Using a die shear tester (Series 4000, manufactured by Dage Arctek Co., Ltd.), die shear test was carried out under the conditions of a shear test speed of 100 μm/sec. A 120 μm long and 30 μm wide sample of a cured pattern film was peeled from the long side and the maximum peel strength was measured at 7 positions, followed by calculating the average to represent the contact strength. A sample is considered to be acceptable in terms of contact strength if it is 60 mN or more, and it is more preferably 180 mN or more and still more preferably 420 mN or more.

### Synthesis Example 1: Synthesis of Hydroxyl-Containing Acid Anhydride (a)

In a dry nitrogen air flow, 18.3 g (0.05 mole) of 2,2-bis(3-amino-4-hydroxyphenyl) hexafluoropropane (BAHF) and 34.0 g (0.3 mole) of allyl glycidyl ether were dissolved in 100 g of γ-butyrolactone (GBL) and cooled to −15° C. To this, a solution of 22.1 g (0.11 mole) of trimellitic anhydride chloride dissolved in 50 g of GBL was added dropwise while controlling the reaction liquid temperature at 0° C. or less. After the end of the dropwise addition, the reaction was continued at 0° C. for 4 hours. This solution was condensed by a rotary evaporator and poured into 1 liter of toluene to provide a hydroxyl-containing acid anhydride (a) as represented by the formula given below.

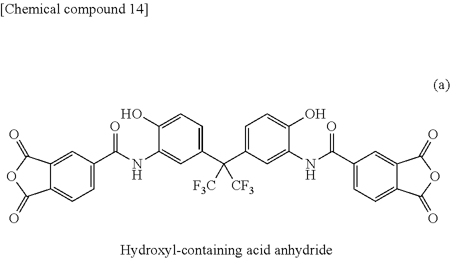 [SMILES: O=C(Nc1cc(C(c2ccc(O)c(NC(=O)c3ccc4c(c3)C(=O)OC4=O)c2)(C(F)(F)F)C(F)(F)F)ccc1O)c1ccc2c(c1)C(=O)OC2=O]

### Synthesis Example 2: Synthesis of Hydroxyl-Containing Diamine Compound (b)

First, 18.3 g (0.05 mole) of BAHF was dissolved in 100 mL of acetone and 17.4 g (0.3 mole) of propylene oxide and cooled to −15° C. To this, a solution of 20.4 g (0.11 mole) of 3-nitrobenzoyl chloride dissolved in 100 mL of acetone was added dropwise. After the end of the dropwise addition, the reaction was continued at −15° C. for 4 hours, followed by leaving the solution to return to room temperature. White solid precipitate formed and it was separated by filtering and vacuum-dried at 50° C.

A 30 g portion of the resulting solid material was put in a 300 mL stainless steel autoclave and dispersed in 250 mL of methyl cellosolve, followed by adding 2 g of 5% palladium-carbon. Hydrogen was introduced into this liquid using a balloon and it was stirred violently. In about 2 hours, the reaction was finished after checking that the balloon would deflate no more. After the end of the reaction, the solution was filtrated to remove the palladium compound used as catalyst and concentrated with a rotary evaporator to provide a hydroxyl-containing diamine compound (b) as represented by the formula given below.

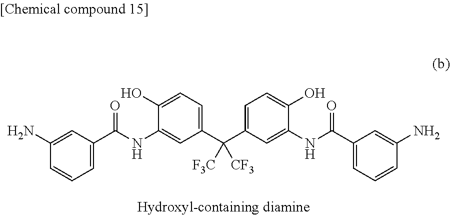 [SMILES: Nc1cccc(C(=O)Nc2cc(C(c3ccc(O)c(NC(=O)c4cccc(N)c4)c3)(C(F)(F)F)C(F)(F)F)ccc2O)c1]

### Synthesis Example 3: Synthesis of Hydroxyl-Containing Diamine Compound (c)

First, 15.4 g (0.1 mole) of 2-amino-4-nitrophenol was dissolved in 50 mL of acetone and 30 g (0.34 mole) of propylene oxide and cooled to −15° C. To this, a solution of 11.2 g (0.055 mole) of isophthalic acid chloride dissolved in 60 mL of acetone was added dropwise. After the end of dropping, reaction was continued at −15° C. for 4 hours. Subsequently, the solution was left to stand to return to room temperature and the resulting precipitate was collected by filtering.

This precipitate was dissolved in 200 mL of GBL and, after adding 3 g of 5% palladium-carbon, stirred violently. A balloon containing hydrogen gas was attached and stirring was continued at room temperature until the hydrogen gas balloon would deflate no more, followed by stirring for additional 2 hours with the hydrogen gas balloon attached. After the end of stirring, filtering was performed to remove the palladium compound that was used as catalyst and the solution was condensed by a rotary evaporator to halve its volume. Ethanol was added to this solution and recrystallization was performed to produce a crystal of hydroxyl-containing diamine (c) as represented by the formula given below.

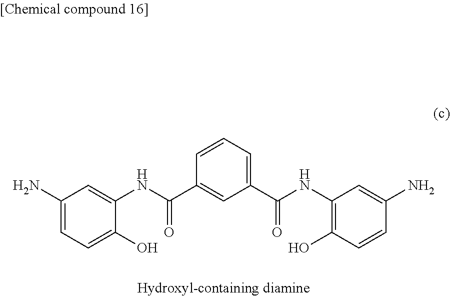 [SMILES: Nc1ccc(O)c(NC(=O)c2cccc(C(=O)Nc3cc(N)ccc3O)c2)c1]

### Synthesis Example 4: Synthesis of Hydroxyl-Containing Diamine Compound (d)

First, 15.4 g (0.1 mole) of 2-amino-4-nitrophenol was dissolved in 100 mL of acetone and 17.4 g (0.3 mole) of propylene oxide and cooled to −15° C. To this, a solution of 20.4 g (0.11 mole) of 4-nitrobenzoyl chloride dissolved in 100 mL of acetone was gradually added dropwise. After the end of dropping, reaction was continued at −15° C. for 4 hours. Subsequently, the solution was left to stand to return to room temperature and the resulting precipitate was collected by filtering. Then, the same procedure as in Synthesis example 2 was carried out to provide a crystal of hydroxyl-containing diamine (d) as represented by the formula given below.

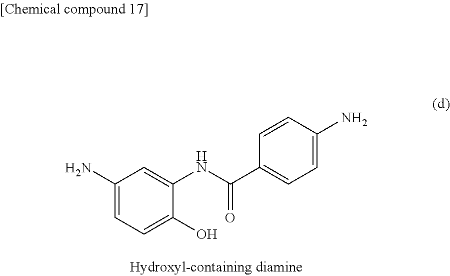 [SMILES: Nc1ccc(C(=O)Nc2cc(N)ccc2O)cc1]

### Synthesis Example 5: Synthesis of Quinone Diazide Compound (e)

First, 21.23 g (0.050 mole) of TrisP-PA (trade name, manufactured by Honshu Chemical Industry Co., Ltd.) and 37.69 g (0.140 mole) of 5-naphthoquinonediazidosulfonyl chloride (NAC5) were put in a 2 L flask, dissolved in 450 g of 1,4-dioxane, and maintained at room temperature. To this solution, 12.85 g of triethyl amine mixed with 50 g of 1,4-dioxane was added dropwise while maintaining the liquid below 35° C. After the dropping, it was stirred at 40° C. for 2 hours. The triethylamine salt was filtered and the filtrate was put in water. Subsequently, the resulting precipitate was collected by filtering. The resulting precipitate was dried in a vacuum dryer to provide a quinone diazide compound (e) as represented by the following formula.

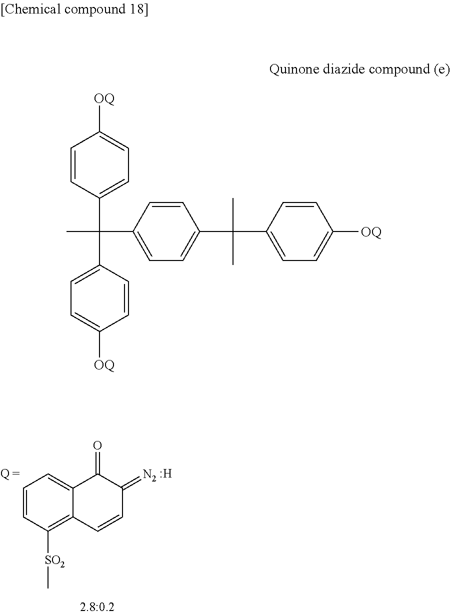

### Synthesis Example 6: Synthesis of Quinone Diazide Compound (f)

Except for using 4-naphthoquinonediazidosulfonyl chloride (NAC4) instead of NAC5, the same procedure as in Synthesis example 5 was carried out to provide a quinone diazide compound (f) as represented by the following formula.

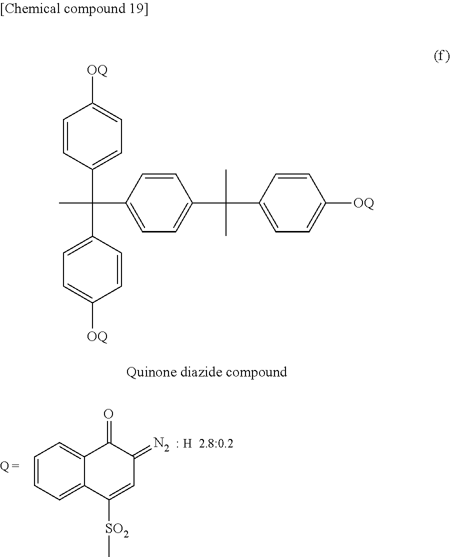

### Synthesis Example 7: Synthesis of Phenol Resin A

In a dry nitrogen flow, 70.2 g (0.65 mole) of m-cresol, 37.8 g (0.35 mole) of p-cresol, 75.5 g (formaldehyde 0.93 mole) of a 37 mass % aqueous formaldehyde solution, 0.63 g (0.005 mole) of oxalic acid dihydrate, and 264 g of methyl isobutyl ketone were fed to a 1 L flask and then the 1 L flask was immersed in an oil bath and subjected to condensation polymerization reaction for 4 hours while refluxing the reaction liquid. Subsequently, the temperature of the oil bath was increased by heating for 3 hours, and then the pressure in the 1 L flask was reduced to 40 to 67 hPa to remove volatile matters, followed by cooling to room temperature to provide a solid polymer of phenol resin A. By GPC, its weight average molecular weight was determined to be 3,500.

### Synthesis Example 8: Synthesis of Phenol Resin B

In a dry nitrogen flow, 70.2 g (0.65 mole) of m-cresol, 37.8 g (0.35 mole) of p-cresol, 75.5 g (formaldehyde 0.93 mole) of a 37 mass % aqueous formaldehyde solution, 0.63 g (0.005 mole) of oxalic acid dihydrate, and 264 g of methyl isobutyl ketone were fed to a 1 L flask and then the 1 L flask was immersed in an oil bath and subjected to condensation polymerization reaction for 6 hours while refluxing the reaction liquid. Subsequently, the temperature of the oil bath was increased by heating for 3 hours, and then the pressure in the 1 L flask was reduced to 40 to 67 hPa to remove volatile matters, followed by cooling to room temperature to provide a solid polymer of phenol resin B. By GPC, its weight average molecular weight was determined to be 6,700.

### Synthesis Example 9: Synthesis of Polymer C

In a dried nitrogen flow, 4.60 g (0.023 mole) of 4,4′-diaminophenyl ether (DAE) and 1.24 g (0.005 mole) of 1,3-bis(3-aminopropyl) tetramethyl disiloxane (SiDA) were dissolved in 50 g of N-methyl-2-pyrolidone (NMP). To this, 21.4 g (0.030 mole) of the hydroxyl-containing anhydride (a) prepared in Synthesis example 1 was added together with 14 g of NMP, stirred for 1 hour at 20° C., and stirred for additional 2 hours at 40° C. Subsequently, a solution prepared by diluting 7.14 g (0.06 mole) of N,N-dimethyl formamide dimethyl acetal with 5 g of NMP was added dropwise over 10 minutes. After the dropping, it was stirred at 40° C. for 3 hours. After the end of reaction, the solution was poured in 2 L of water and the resulting solid polymer precipitate was collected by filtering. The solid polymer was dried at 50° C. for 72 hours in a vacuum dryer to provide a polymer C to be used as polyimide precursor. By GPC, it was confirmed that the weight average molecular weight, n, of the resulting polymer was in the range of 10 to 100,000.

### Synthesis Example 10: Synthesis of Polymer D

In a dried nitrogen flow, 13.90 g (0.023 mole) of the hydroxyl-containing diamine (b) prepared in Synthesis example 2 was dissolved in 50 g of NMP. To this, 17.5 g (0.025 mole) of the hydroxyl-containing anhydride (a) prepared in Synthesis example 1 was added together with 30 g of pyridine and stirred for 2 hours at 40° C. Subsequently, a solution prepared by diluting 7.35 g (0.05 mole) of N,N-dimethyl formamide diethyl acetal with 5 g of NMP was added dropwise over 10 minutes. After the dropping, it was stirred at 40° C. for 2 hours. After the end of reaction, the solution was poured in 2 L of water and the resulting solid polymer precipitate was collected by filtering. The solid polymer was dried at 80° C. for 72 hours in a vacuum dryer to provide a polymer D to be used as polyimide precursor. By GPC, it was confirmed that the weight average molecular weight, n, of the resulting polymer was in the range of 10 to 100,000.

### Synthesis Example 11: Synthesis of Polymer E

In a dried nitrogen flow, 15.13 g (0.040 mole) of the hydroxyl-containing diamine compound (c) prepared in Synthesis example 3 and 1.24 g (0.005 mole) of SiDA were dissolved in 50 g of NMP. To this, 15.51 g (0.05 mole) of 3,3′,4,4′-diphenyl ether tetracarboxylic anhydride (ODPA) was added together with 21 g of NMP, stirred for 1 hour at 20° C., and stirred for additional 1 hour at 50° C. Subsequently, a solution prepared by diluting 13.2 g (0.09 mole) of N,N-dimethyl formamide diethyl acetal with 15 g of NMP was added dropwise over 10 minutes. After the dropping, it was stirred at 40° C. for 3 hours. After the end of reaction, the solution was poured in 2 L of water and the resulting solid polymer precipitate was collected by filtering. The solid polymer was dried at 80° C. for 72 hours in a vacuum dryer to provide a polymer E to be used as polyimide precursor. By GPC, it was confirmed that the weight average molecular weight, n, of the resulting polymer was in the range of 10 to 100,000.

### Synthesis Example 12: Synthesis of Polymer F

In a dried nitrogen flow, 4.37 g (0.018 mole) of the hydroxyl-containing diamine compound (d) prepared in Synthesis example 4, 4.51 g (0.0225 mole) of DAE, and 0.62 g (0.0025 mole) of SiDA were dissolved in 70 g of NMP. To this solution, 24.99 g (0.035 mole) of the hydroxyl-containing anhydride (a) prepared in Synthesis example 1 and 4.41 g (0.010 mole) of 3,3′,4,4′-biphenyl tetracarboxylic dianhydride (BPDA) were added together with 25 g of NMP, stirred for 1 hour at room temperature, and then stirred for additional 1 hour at 40° C. Subsequently, a solution prepared by diluting 13.09 g (0.11 mole) of N,N-dimethyl formamide dimethyl acetal with 5 g of NMP was added dropwise over 10 minutes. After the dropping, it was stirred at 40° C. for 3 hours. After the end of reaction, the solution was poured in 2 L of water and the resulting solid polymer precipitate was collected by filtering. The solid polymer was dried at 80° C. for 72 hours in a vacuum dryer to provide a polymer F to be used as polyimide precursor. By GPC, it was confirmed that the weight average molecular weight, n, of the resulting polymer was in the range of 10 to 100,000.

### Synthesis Example 13: Synthesis of Polymer G

In a dry nitrogen flow, 4.40 g (0.022 mole) of DAE and 1.24 g (0.005 mole) of SiDA were dissolved in 50 g of NMP. To this, 21.4 g (0.030 mole) of the hydroxyl-containing anhydride (a) prepared in Synthesis example 1 was added together with 14 g of NMP, reacted for 1 hour at 20° C., and then stirred for 2 hours at 40° C. Subsequently, 0.71 g (0.006 mole) of 4-ethynylaniline was added as end capping agent and the reaction was continued at 40° C. for 1 hour. Subsequently, a solution prepared by diluting 7.14 g (0.06 mole) of N,N-dimethyl formamide dimethyl acetal with 5 g of NMP was added dropwise over 10 minutes. After the dropping, it was stirred at 40° C. for 3 hours. After the end of reaction, the solution was poured in 2 L of water and the resulting solid polymer precipitate was collected by filtering. The solid polymer was dried at 50° C. for 72 hours in a vacuum dryer to provide a polymer G to be used as polyimide precursor. By GPC, it was confirmed that the weight average molecular weight, n, of the resulting polymer was in the range of 10 to 100,000.

### Synthesis Example 14: Synthesis of Polymer H

In a dried nitrogen flow, 1 mole of diphenyl ether 4,4′-dicarboxylic acid dichloride (DEDC) and 2 moles of 1-hydroxybenzotriazole were reacted and 19.70 g (0.040 mole) of the resulting dicarboxylic acid derivative and 18.31 g (0.050 mole) of BAHF were dissolved in 200 g of NMP and stirred at 75° C. for 12 hours to end the reaction. After the end of reaction, the solution was poured in 3 L of a 3/1 (volume ratio) water/methanol solution and the resulting solid polymer precipitate was collected by filtering. The solid polymer was dried at 80° C. for 20 hours in a vacuum dryer to provide a polymer H to be used as polybenzoxazole precursor. By GPC, it was confirmed that the weight average molecular weight, n, of the resulting polymer was in the range of 10 to 100,000.

### Synthesis Example 15: Synthesis of Polymer I

In a dried nitrogen flow, 48.1 g (0.241 mole) of DAE and 25.6 g (0.103 mole) of SiDA were dissolved in 820 g of NMP and, after adding 105 g (0.338 mole) of ODPA, stirred for 8 hours while controlling the temperature in the range of 10° C. or more and 30° C. or less to provide a polymer solution I to be used as polyimide precursor. By GPC, it was confirmed that the weight average molecular weight, n, of the resulting polymer was in the range of 10 to 100,000.

### Synthesis Example 16: Synthesis of Polymer J

In a dried nitrogen flow, 198 g (0.797 mole) of SiDA was dissolved in 600 g of NMP and, after adding 123.6 g (0.398 mole) of ODPA and 78.2 g (0.798 mole) of maleic anhydride, stirred for 8 hours while controlling the temperature in the range of 10° C. or more and 30° C. or less to provide a polymer solution J to be used as polyimide precursor. By GPC, it was confirmed that the weight average molecular weight, n, of the resulting polymer was in the range of 10 to 100,000.

### Synthesis Example 17: Synthesis of Polymer K

In a dried nitrogen flow, 1 mole of sebacic acid dichloride and 2 moles of 1-hydroxybenzotriazole were reacted and 17.47 g (0.040 mole) of the resulting dicarboxylic acid derivative and 18.31 g (0.050 mole) of BAHF were dissolved in 200 g of NMP and stirred at 75° C. for 12 hours to end the reaction. After the end of reaction, the solution was poured in 3 L of a 3/1 (volume ratio) water/methanol solution and the resulting solid polymer precipitate was collected by filtering. The solid polymer was dried at 80° C. for 20 hours in a vacuum dryer to provide a polymer K to be used as polybenzoxazole precursor. By GPC, it was confirmed that the weight average molecular weight, n, of the resulting polymer was in the range of 10 to 100,000.

### Synthesis Example 18: Synthesis of Polymer L

In a dry nitrogen flow, 15.5 g (0.2 mole) of ODPA was dissolved in 250 g of N-methyl pyrolidone. To this solution, 11.9 g (0.13 mole) of BAHF, 3.5 g (0.06 mole) of 1-(2-(2-(2-aminopropoxy)ethoxy)propoxy) propane-2-amine, and 0.6 g (0.01 mole) of 1,3-bis(3-aminopropyl)tetramethyl disiloxane, which are diamines with an ethylene glycol or propylene glycol backbone, were added together with 250 g NMP, reacted at 60° C. for 1 hour, and then further reacted at 200° C. for 6 hours. After the end of reaction, the solution was cooled to room temperature and then the solution was poured in 2.5 L of water to produce a white precipitate. This precipitate was collected by filtering, rinsed with water three times, and dried in a vacuum dryer at 80° C. for 40 hours to provide a polyimide copolymer L, which was the intended resin. Its imidization degree was 96%.

### Synthesis Example 19: Synthesis of Polymer M

In a dry nitrogen flow, 15.5 g (0.2 mole) of ODPA was dissolved in 250 g of NMP. To this solution, 10.1 g (0.11 mole) of BAHF and 3.9 g (0.07 mole) of 1-((1-((1-(2-aminopropoxy) propane-2-yl)oxy)propane-2-yl)oxy) propane-2-amine, which is a diamine with a propylene glycol backbone, were added together with 50 g of NMP, and after adding 1.1 g (0.04 mole) of 3-aminophenol, as end capping agent, and 12.5 g of NMP, reacted at 60° C. for 1 hour, and further reacted at 180° C. for 6 hours. After the end of reaction, the solution was cooled to room temperature and then the solution was poured in 2.5 L of water to produce a white precipitate. This precipitate was collected by filtering, rinsed with water three times, and dried in a vacuum dryer at 80° C. for 40 hours to provide a polyimide copolymer M, which was the intended resin. Its imidization degree was 91%.

### Synthesis Example 20: Synthesis of Polymer N

In a dried nitrogen flow, 1 mole of 2,2-bis(4-carboxyphenyl)hexafluoropropane dichloride and 2 moles of 1-hydroxybenzotriazole were reacted and 23.58 g (0.040 mole) of the resulting dicarboxylic acid derivative and 18.31 g (0.050 mole) of BAHF were dissolved in 200 g of NMP and stirred at 75° C. for 12 hours to end the reaction. After the end of reaction, the solution was poured in 3 L of a 3/1 (volume ratio) water/methanol solution and the resulting solid polymer precipitate was collected by filtering. The solid polymer was dried at 80° C. for 20 hours by a vacuum dryer to provide a polymer N to be used as polybenzoxazole precursor. By GPC, it was confirmed that the weight average molecular weight, n, of the resulting polymer was in the range of 10 to 100,000.

Photosensitive resin film was prepared from varnish formed of each of the 18 photosensitive resin compositions that are given in Tables 1 and 2 (Examples 1 to 32 and Comparative examples 1 to 6) and its pattern processability [minimum exposure (Eth)] was evaluated. Evaluation was also performed for the contact [adhesion strength] of each cured pattern film with copper after reflow treatment. For the photosensitive resin compositions, each of the polymers C to K and N prepared in Synthesis examples 9 to 17 and 20, respectively, was used as the resin (a-1) having, as primary component, a structure as represented by general formula (1), and shown as C to K and N in the “type of resin (a-1)” column in Tables 1 and 2. The polymers L or M prepared in Synthesis example 18 or 19 was used as the polyimide (a-2) and shown as L or M in the “type of resin (a-2)” column in Tables 1 and 2. In addition, the phenol resin A or B prepared in Synthesis example 7 or 8 was used as the phenol resin (b) and shown as A or B in the “type of phenol resin (b)” column in Tables 1 and 2. Furthermore, trimethylpyridine or triethylpyridine was used as the compound (c) having, as primary component, a structure as represented by general formula (2) and shown in the “compound (c)” column in Tables 1 and 2. Pyridine was used instead of the compound (c) in Comparative example 5. The quinone diazide compound (e) or (f) prepared in Synthesis example 5 or 6 was used as the quinone diazide compound and shown as (e) or (f) in the “type of quinone diazide compound” column in Tables 1 and 2. Gamma (γ)-butyrolactone (GBL) was used and shown as the solvent in Tables 1 and 2.

### Example 1

To prepare varnish of a positive type photosensitive resin composition, 7.0 g of the polymer C, 3.0 g of the phenol resin A, 0.01 g of trimethylpyridine, and 1.5 g of the quinone diazide compound (f) were weighed out and dissolved in 15.0 g of GBL. The varnish obtained was subjected to evaluation for pattern processability [minimum exposure (Eth)] and contact with copper [adhesion strength] as described above.

### Examples 2 to 33 and Comparative Examples 1 to 6

Except for using the polyimide/novolac resin ratios and the other additives given in Tables 1 and 2, the same procedure as in Example 1 was carried out to prepare varnish, which was then subjected to evaluation test for pattern processability and contact with copper.

TABLE 1

| | | | | | | | | | quinone | | | |
|---|---|---|---|---|---|---|---|---|---|---|---|---|
| | resin | | resin | | phenol resin | | compound | | diazide | | | |
| | (a-1) | | (a-2) | | (b) | | (c) | | compound | | solvent | |
| | | weight | | weight | | weight | | weight | | weight | | weight |
| | type | (g) | type | (g) | type | (g) | type | (g) | type | (g) | type | (g) |
| Example 1 | C | 7.0 | | | A | 3.0 | trimethyl pyridine | 0.01 | (f) | 1.5 | GBL | 15 |
| Example 2 | D | 7.0 | | | A | 3.0 | trimethyl pyridine | 0.01 | (f) | 1.5 | GBL | 15 |
| Example 3 | E | 7.0 | | | A | 3.0 | trimethyl pyridine | 0.01 | (f) | 1.5 | GBL | 15 |
| Example 4 | F | 7.0 | | | A | 3.0 | trimethyl pyridine | 0.01 | (f) | 1.5 | GBL | 15 |
| Example 5 | G | 7.0 | | | A | 3.0 | trimethyl pyridine | 0.01 | (f) | 1.5 | GBL | 15 |
| Example 6 | H | 7.0 | | | B | 3.0 | trimethyl pyridine | 0.1 | (e) | 1.5 | GBL | 15 |
| Example 7 | I | 8.5 | | | B | 1.5 | triethyl pyridine | 0.01 | (e) | 1.5 | GBL | 12 |
| Example 8 | J | 8.5 | | | B | 1.5 | triethyl pyridine | 0.01 | (e) | 1.5 | GBL | 12 |
| Example 9 | N | 7.0 | | | B | 3.0 | triethyl pyridine | 0.1 | (e) | 1.5 | GBL | 12 |
| Example 10 | | | L | 8.0 | A | 2.0 | triethyl pyridine | 0.01 | (e) | 1.3 | GBL | 15 |
| Example 11 | | | M | 8.0 | A | 2.0 | triethyl pyridine | 0.01 | (e) | 1.3 | GBL | 15 |
| Example 12 | H | 5.0 | | | B | 5.0 | triethyl pyridine | 0.1 | (f) | 1.5 | GBL | 15 |
| Example 13 | H | 2.0 | | | B | 8.0 | triethyl pyridine | 0.1 | (f) | 1.5 | GBL | 15 |
| Example 14 | D | 5.0 | | | B | 5.0 | triethyl pyridine | 0.005 | (f) | 1.5 | GBL | 15 |
| Example 15 | D | 2.0 | | | B | 8.0 | triethyl pyridine | 0.005 | (f) | 1.5 | GBL | 15 |
| Example 16 | H | 7.0 | | | B | 3.0 | trimethyl pyridine | 0.025 | (e) | 1.5 | GBL | 15 |
| Example 17 | H | 7.0 | | | B | 3.0 | trimethyl pyridine | 0.03 | (e) | 1.5 | GBL | 15 |
| Example 18 | H | 7.0 | | | B | 3.0 | trimethyl pyridine | 0.045 | (e) | 1.5 | GBL | 15 |
| Example 19 | H | 7.0 | | | B | 3.0 | trimethyl pyridine | 0.05 | (e) | 1.5 | GBL | 15 |
| Example 20 | C | 10.0 | | | | | trimethyl pyridine | 0.005 | (f) | 1.5 | GBL | 15 |
| Example 21 | D | 10.0 | | | | | trimethyl pyridine | 0.005 | (f) | 1.5 | GBL | 15 |
| Example 22 | E | 10.0 | | | | | trimethyl pyridine | 0.005 | (f) | 1.5 | GBL | 15 |
| Example 23 | F | 10.0 | | | | | trimethyl pyridine | 0.005 | (f) | 1.5 | GBL | 15 |
| Example 24 | G | 10.0 | | | | | trimethyl pyridine | 0.005 | (f) | 1.5 | GBL | 15 |
| Example 25 | H | 10.0 | | | | | trimethyl pyridine | 0.1 | (e) | 1.5 | GBL | 15 |
| Example 26 | | | L | 10.0 | | | triethyl pyridine | 0.01 | (e) | 1.3 | GBL | 15 |
| Example 27 | | | M | 10.0 | | | triethyl pyridine | 0.0005 | (e) | 1.3 | GBL | 15 |
| Example 28 | F | 7.0 | | | A | 3.0 | trimethyl pyridine | 0.0005 | (f) | 1.5 | GBL | 15 |
| Example 29 | K | 10.0 | | | | | trimethyl pyridine | 0.04 | (e) | 1.5 | GBL | 12 |
| Example 30 | K | 10.0 | | | | | trimethyl pyridine | 0.045 | (e) | 1.5 | GBL | 12 |
| Example 31 | K | 10.0 | | | | | trimethyl pyridine | 0.065 | (e) | 1.5 | GBL | 12 |
| Example 32 | K | 10.0 | | | | | trimethyl pyridine | 0.08 | (e) | 1.5 | GBL | 12 |
| Example 33 | C | 5.0 | L | 5.0 | | | trimethyl pyridine | 0.01 | (f) | 1.4 | GBL | 15 |

TABLE 2

| | | | | | | | | | quinone | | | |
|---|---|---|---|---|---|---|---|---|---|---|---|---|
| | | | | | phenol | | | | diazide | | | |
| | resin (a-1) | | resin (a-2) | | resin (b) | | compound (c) | | compound | | solvent | |
| | | weight | | weight | | weight | | weight | | weight | | weight |
| | type | (g) | type | (g) | type | (g) | type | (g) | type | (g) | type | (g) |
| Comparative | C | 10.0 | | | | | | | (f) | 1.5 | GBL | 15 |
| example 1 | | | | | | | | | | | | |
| Comparative | | | L | 10.0 | | | | | (e) | 1.3 | GBL | 15 |
| example 2 | | | | | | | | | | | | |
| Comparative | H | 10.0 | | | | | | | (e) | 1.5 | GBL | 15 |
| example 3 | | | | | | | | | | | | |
| Comparative | K | 8.5 | | | | | | | (e) | 1.5 | GBL | 12 |
| example 4 | | | | | | | | | | | | |
| Comparative | K | 8.5 | | | | | pyridine | 0.1 | (e) | 1.5 | GBL | 12 |
| example 5 | | | | | | | | | | | | |
| Comparative | | | | | A | 10.0 | trimethyl | 0.01 | (f) | 1.5 | GBL | 15 |
| example 6 | | | | | | | pyridine | | | | | |

Results are given in Tables 3 and 4.

TABLE 3

| | minimum exposure (Eth) | adhesion strength |
|---|---|---|
| | (mJ/cm²) | (mN) |
| Example 1 | 200 | 358 |
| Example 2 | 180 | 309 |
| Example 3 | 195 | 345 |
| Example 4 | 185 | 323 |
| Example 5 | 185 | 340 |
| Example 6 | 165 | 410 |
| Example 7 | 245 | 292 |
| Example 8 | 240 | 274 |
| Example 9 | 170 | 405 |
| Example 10 | 280 | 253 |
| Example 11 | 300 | 250 |
| Example 12 | 120 | 405 |
| Example 13 | 100 | 321 |
| Example 14 | 150 | 195 |
| Example 15 | 115 | 185 |
| Example 16 | 155 | 412 |
| Example 17 | 155 | 432 |
| Example 18 | 160 | 437 |
| Example 19 | 160 | 415 |
| Example 20 | 340 | 145 |
| Example 21 | 400 | 110 |
| Example 22 | 355 | 141 |
| Example 23 | 390 | 112 |
| Example 24 | 365 | 128 |
| Example 25 | 315 | 172 |
| Example 26 | 450 | 83 |
| Example 27 | 480 | 66 |
| Example 28 | 230 | 98 |
| Example 29 | 300 | 68 |
| Example 30 | 305 | 75 |
| Example 31 | 305 | 77 |
| Example 32 | 310 | 63 |
| Example 33 | 330 | 220 |

TABLE 4

| | minimum exposure (Eth) | adhesion strength |
|---|---|---|
| | (mJ/cm²) | (mN) |
| Comparative | 350 | 31 |
| example 1 | | |
| Comparative | 620 | 35 |
| example 2 | | |
| Comparative | 330 | 24 |
| example 3 | | |
| Comparative | 310 | 26 |
| example 4 | | |
| Comparative | 630 | 65 |
| example 5 | | |
| Comparative | 80 | 20 |
| example 6 | | |

### EXPLANATION OF NUMERALS

1. semiconductor device
2. passivation film
3. resin film
4. metal wiring
5. resin film

1. A photosensitive resin composition comprising an alkali-soluble resin which contains at least one selected from the group consisting of a resin (a-1) which contains, as primary component, a structure as represented by the undermentioned general formula (1), polyimides (a-2) and copolymers thereof, and a compound (c) which contains, as primary component, a structure as represented by the undermentioned general formula (2): 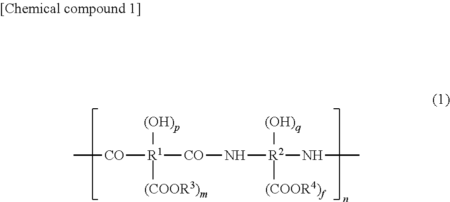
wherein R¹ and R² in general formula (1) may be identical to or different from each other and each represent a divalent to octavalent organic group having 2 or more carbon atoms; R³ and R⁴ may be identical to or different from each other and each represent either a hydrogen atom or an organic group having 1 to 20 carbon atoms; n is an integer of 10 to 100,000; m and f are independently an integer of 0 to 2; p and q are independently an integer of 0 to 4; and m+q≠0 and p+q≠0; and 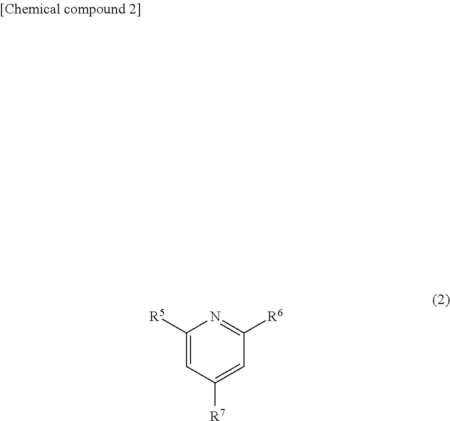
wherein R⁵, R⁶, and R⁷ in general formula (2) given above may be identical to or different from each other and each represent either a hydrogen atom or a monovalent organic group having 1 or more carbon atoms; and at least one of R⁵, R⁶, and R⁷ is a monovalent organic group having 1 or more carbon atoms.

2. A photosensitive resin composition as claimed in claim 1, wherein the compound (c) having, as primary component, a structure as represented by general formula (2) accounts for 0.42 part by mass or more and 0.68 part by mass or less relative to 100 parts by mass of the alkali-soluble resin which contains at least one selected from the group consisting of the resin (a-1) having, as primary component, a structure as represented by the aforementioned general formula (1), polyimides (a-2) and copolymers thereof.

3. A photosensitive resin composition as claimed in claim 1 further comprising a phenol resin (b).

4. A photosensitive resin composition as claimed in claim 3, wherein the quantities of the alkali-soluble resin which contains at least one selected from the group consisting of the resin (a-1) which contains, as primary component, a structure as represented by the aforementioned general formula (1), polyimides (a-2) and copolymers thereof, and the phenol resin (b) meet the relation ((a-1)+(a-2))/(b)=95/5 to 5/95 (mass ratio).

5. A photosensitive resin composition as claimed in claim 3, wherein the phenol resin (b) has a weight average molecular weight of 2,000 to 15,000.

6. A photosensitive resin composition as claimed in claim 3, wherein the phenol resin (b) is a novolac resin.

7. A cured pattern film formed by curing a photosensitive resin composition as claimed in claim 1.

8. A production method for cured pattern films comprising a photosensitive resin film formation step for applying and drying a photosensitive resin composition as claimed in claim 1 on a substrate to form a photosensitive resin film, a light exposure step for exposing the photosensitive resin film to light through a mask, a development step for developing the light-exposed photosensitive resin film with an aqueous alkali solution to form a pattern resin film, and heat treatment step for heat-treating the pattern resin film to form a cured film.

9. A semiconductor apparatus comprising a cured pattern film as claimed in claim 7 to serve as a surface protection film layer.

10. A semiconductor apparatus comprising a cured pattern film as claimed in claim 7 to serve as an insulation film in forming a re-wiring layer.

11. A semiconductor apparatus as claimed in claim 9, having a cured pattern film with a film thickness of 2 to 15 μm present on a substrate, copper wiring present thereon, and another cured pattern film with a film thickness of 2 to 15 μm present between copper wires to serve as an insulation film.
